(19) United States
(12) Patent Application Publication
(10) Pub. No.: US 2025/0128632 A1
(43) Pub. Date: Apr. 24, 2025

(54) Charging Strategies for Electric Vehicles

(71) Applicant: InductEV, Inc., King of Prussia, PA (US)

(72) Inventors: Anthony W. Calabro, Devon, PA (US); Erik Langenborg, Quakertown, PA (US); Timothy James Near, Contoocook, NH (US)

(21) Appl. No.: 18/986,643

(22) Filed: Dec. 18, 2024

Related U.S. Application Data
(63) Continuation-in-part of application No. 18/232,659, filed on Aug. 10, 2023.
Application No. 18/232,659 is a continuation-in-part of application No. 18/131,189, filed on Apr. 5, 2023.
(60) Provisional application No. 63/436,419, filed on Dec. 30, 2022.

(51) Int. Cl. B60L 53/64; B60L 53/12; B60L 53/62; B60L 53/68; G01R 31/36; G01R 31/367

(52) U.S. Cl. CPC B60L 53/64; B60L 53/12; B60L 53/62; B60L 53/68; G01R 31/3647; G01R 31/3648; G01R 31/367

(57) ABSTRACT

A system and method that manages charging of Electric Vehicles (EVs) at a depot equipped with EV chargers. For each EV arriving at the depot, data is collected from the EV including a current state of charge (SoC), an SoC goal, a route estimate, and a charging schedule. A depot controller determines from the collected data a charging priority for the EV relative to other EVs at the depot. When charging is required to meet the SoC goal of the EV, a charger is selected for charging the EV and a charging start time and charging duration is determined by an optimization algorithm that concurrently optimizes a minimal total cost of electricity for total power transferred to the EV during charging while maximizing a probability of the EV leaving the depot with its SoC goal satisfied.

### CROSS REFERENCE TO RELATED APPLICATIONS

This application is a continuation-in-part of U.S. patent application Ser. No. 18/232,659 filed Aug. 10, 2023, which is a continuation-in-part of U.S. patent application Ser. No. 18/131,189 filed Apr. 5, 2023, which claims the benefit of U.S. Provisional Application No. 63/436,419 filed Dec. 30, 2022, all of which are incorporated by reference as if fully set forth herein.

### FIELD OF INVENTION

The present disclosure relates generally to wireless power transfer, and more specifically to devices, systems, and methods related to wireless power transfer to remote systems such as vehicles including batteries. More particularly, the present disclosure relates to charging strategies for electric vehicles including achieving lowest total cost of travel for electric vehicles on known routes using directional and bi-directional wireless power transfer opportunity charging and providing peak shaving when providing charging as a service for individual electric vehicles and fleets of electric vehicles.

### BACKGROUND

Increasingly, transit, drayage, taxis and delivery vehicles are evolving to electric traction motor and battery power.

A transit bus is a fixed route public transportation service which operates according to a set (pre-published) schedule which includes arrival and departure times for geographically distributed passenger stops where passengers may enter or exit the vehicle. A terminal, or terminus, is where a transit route starts or ends and where drivers may dismount briefly or be exchanged. A terminal may also include a stop where passengers board and alight from vehicles. A bus depot may be a terminal that serves bus passengers (a stop), but also can be the nexus between different bus routes and bus lines. The depot can also provide battery charging, vehicle maintenance, vehicle storage, and refreshment, relief, and staging for bus drivers.

Drayage is the process of transporting goods over short distances. A drayage vehicle operates in a bounded area, altering its route as needed to pick-up, move, and deliver freight among the multiple destinations.

Delivery vehicles may be operated in several ways depending on the service type. A package delivery vehicle may start full at a loading dock, depot, or terminal and then deliver to a single or multiple drop-off locations over public roads. The package vehicle may also load at any drop-off location or at pre-set pick-up locations in a service area or along a pre-set route. Delivery routes may be fixed, malleable (with both pre-set stops and new stops added during a delivery run), or ad hoc (with the next stop determined during or after completion of a current inter-stop run). A taxi passenger service or ride-share is a good example of a fully ad hoc delivery service.

Static Opportunity charging of electric vehicles (EVs) during brief stops or at vehicle loading, unloading, and package sorting is an important application of wireless power transfer (WPT). EVs may be human operated, use driver-assistance automation, or be fully autonomous.

WPT offers fully automatic power delivery to the EV without need for a physical (wired) power connection. With WPT, the driver has no need to exit the vehicle to attach a power cable (if exiting the vehicle for or while charging is permitted at all). Also known as Inductively Coupled Power Transfer, WPT acts as an open core transformer with a primary (ground-side) coil and a secondary (vehicle-side) coil to transfer power over an air-gap in accordance to Faraday's first law of electromagnetic induction.

### SUMMARY

Various examples are now described to introduce a selection of concepts in a simplified form that are further described below in the Detailed Description. The Summary is not intended to be used to limit the scope of the claimed subject matter.

In sample embodiments, a system is provided for managing the charging of Electric Vehicles (EVs) at a depot. The system includes at least one charger, a wireless communication system for communicating with EVs, and a depot controller. The depot controller includes a processor that executes instructions to perform operations including:
receiving from the wireless communication system an indication that an EV has arrived at the depot;
for each EV arriving at the depot:
collecting data from the EV including a current state of charge (SoC), an SoC goal, a route estimate, and a charging schedule;
from the collected current SoC, SoC goal, route estimate, and charging schedule for the EV, determining a charging priority for the EV relative to other EVs at the depot; and
determining whether charging is required to meet the SoC goal of the EV and, if so, selecting a charger of the at least one charger for charging the EV and determining a charging start time and charging duration for the EV in accordance with the charging priority and the SoC goal of the EV,
wherein the instructions executed by the processor implement an optimization algorithm that determines the start time and charging duration by concurrently optimizing a minimal total cost of electricity for total power transferred to the EV during charging at the depot while maximizing a probability of the EV leaving the depot with its SoC goal satisfied.

In sample configurations, the system further includes a dispatch server. The depot controller queries the dispatch server for or downloads schedule routes for a next service period of the EV and determines from the schedule routes a departure time for the EV, the SoC goal of the EV, and electrical rate structure for the at least one EV charger. The depot controller further queries the EV arriving at the depot via the wireless communication system for the current SoC and charging capabilities of the EV. The depot controller may further execute instructions to infer the current SoC of the arriving EV for a next service period from the EV's history on a route to the depot or from a history of a similar EV that has previously completed the route to the depot. The depot controller also may select the charger for charging the EV by determining the charging start time for the EV and selecting a charger available at the charging start time.

In the sample configurations, when the charger for charging the EV is unavailable, the depot controller may further direct the EV to a standby position until the charging start time. Also, upon arrival of another EV with a higher charging priority, the depot controller may execute instructions to recalculate at least the charging start time for the EV when the EV is in the standby position.

In the sample configurations, the optimization algorithm may include instructions, that when executed by the processor, implement electricity peak shaving to manage time of use of the at least one charger to take advantage of variable electricity rates at different times for charging to lower total electrical cost of the depot to a local optimum in accordance with electrical charging needs of EVs served by the depot. The optimization algorithm may further include instructions, that when executed by the processor, implement a first-in-first-scheduled algorithm that schedules the EV for charging based on its time of arrival at the depot.

Alternatively, the optimization algorithm includes instructions, that when executed by the processor, implement a delta algorithm that schedules the EV for charging based on a size of a delta between its SoC and the SoC goal. The delta algorithm may include instructions that, when executed by the processor, use predicted or historical data of the EV and a scheduled depot arrival time to pre-populate the charging schedule for the EV. The delta algorithm may further include instructions that, when executed by the processor, use cost of power at each charger of the at least one charger to weight use of each charger to favor charging of the EV by an available charger of the at least one charger having a lowest cost of power. The delta algorithm also may include instructions that, when executed by the processor, control the at least one charger to spread available power over all charger/EV combinations at the depot when the EV is not at its SoC goal while keeping instantaneous power use under a desired threshold to minimize a utility demand charge.

In another alternative, the optimization algorithm may include instructions that, when executed by the processor, orders and assigns the EV to a charger in accordance with a charging schedule determined by a dynamic optimization algorithm that uses a weighted reward to encourage charging efficiency in accordance with the following:

$$min {V}_{π} ( s ) = {E}_{π} [ {R}_{t + 1} + γ * {V}_{π} ( {S}_{t + 1} ) \vert {S}_{t} = s ]$$

where:
V_{π}(s) is a value of state s,
E_{π}[Rₜ₊₁] is an expected value of an immediate reward,
E_{π}[γ*V_{π}(Sₜ₊₁)] is a discounted value of a next state,
Sₜ=s is a value if an agent starts at state s,
   and where:

$${R}_{t + 1} = [ {Cost}_{demand} ( t + 1 ) + {Cost}_{tou} ( t + 1 ) + {Cost}_{battery \_ wear} ( t + 1 ) - {Profit}_{operations} ( t + 1 ) ]$$

and:
Cost_{demand} is a demand charge implications for a time step,
Costₜₒᵤ is a time of use (tou) charge for a time step,
Profitₒₚₑᵣₐₜᵢₒₙₛ is a value of operating the EV,
Sₜ is a state at time t,
Rₜ(s) is a reward at time t given state s,
Vₓ(s) is a value of acting on policy π at state s,
E_{π}() is an expected value, and
γ is a fractional discount of future value.

In further configurations, the depot controller may determine the start time and charging duration by executing instructions, that when executed by the processor, produce a charging schedule for the EV, a schedule for the at least one charger, and an aggregate power use schedule for the depot. The depot controller may further execute instructions, that when executed by the processor, determines the charging priority for the EV based on the schedule of the EV, availability of a charger of the at least one charger, and availability of power upon arrival of the EV at the depot.

In still other configurations, the depot controller may execute instructions, that when executed by the processor, determine the charging priority for the EV based on at least one of a departure time of the EV from the depot or a total charging time needed to charge the EV to the SoC goal. The depot controller also may execute instructions, that when executed by the processor, determine the charging priority for the EV by determining a hysteresis value for availability of a charger of the at least one charger and a charging power allocation to increase efficiency of charging over time by preventing delays when a higher priority EV displaces an EV currently being charged.

In yet other configurations, the depot controller may execute instructions, that when executed by the processor, trigger a recalculation of the charging priority of the EV when the EV is removed from charging prematurely where the SoC goal has not been reached, the selected charger or EV faults to prevent the SoC goal from being reached, or the depot experiences a power outage during charging of the EV. In addition, the depot controller may execute instructions, that when executed by the processor, trigger a recalculation of the charging priority of the EV as a result of an SoC change of the EV or a schedule change of the EV as a result of a weather change or weather forecast change. The depot controller also may execute instructions, that when executed by the processor, trigger a recalculation of the charging priority of the EV as a result of addition of a new EV or a previously unserved EV to a fleet of EVs serviced by the depot or a new route added for service by the fleet of EVs serviced by the depot.

In alternative configurations, a charger of the at least one charger may be bi-directional. In such as case, the depot controller may execute instructions, that when executed by the processor, determine that the EV has an SoC at or above its SoC goal and initiates transfer of energy from the EV to a utility grid for electrical arbitrage or local storage for later use at the depot.

Methods of operation of the system for managing the charging of Electric Vehicles (EVs) at a depot are also within the scope of the description provided herein.

This summary section is provided to introduce aspects of the inventive subject matter in a simplified form, with further explanation of the inventive subject matter following in the text of the detailed description. The particular combination and order of elements listed in this summary section is not intended to provide limitation to the elements of the claimed subject matter. Rather, it will be understood that this section provides summarized examples of some of the embodiments described in the Detailed Description below.

### BRIEF DESCRIPTION OF THE DRAWINGS

The foregoing and other beneficial features and advantages of the invention will become apparent from the following detailed description in connection with the attached figures, of which:

FIG. 1 graphically depicts examples of EV range versus battery state of charge (SoC) from a starting charge.

FIG. 2 graphically depicts an example of EV range extension by mid-route recharging.

FIG. 3 graphically depicts an example of range extension and battery lifespan extension by strategic opportunity charging.

FIG. 4 graphically depicts the price of power over a 24-hour time period in an example.

FIG. 5 graphically depicts the price of power from first and second utilities that share the same geographical market with a deployed WPT system and offer different electric rates based on the hourly time-of-day and power generation capabilities and capacities.

FIG. 6 depicts an example where two regions are traversed by an EV route.

FIG. 7 geographically depicts an exemplary distribution of wireless chargers along a bus route.

FIG. 8 is a diagram depicting an example state machine for a transit bus with wireless charging.

FIG. 9 diagrammatically illustrates the case where a single charger is used to service first and second transit routes and thus service multiple EVs that service those routes.

FIG. 10 depicts at a high level the communication paths available for data collection from an EV and from the WPT charger.

FIG. 11 depicts an example wireless charger site.

FIG. 12 is a flow chart of a sample method for strategic opportunity charging in an example configuration.

FIG. 13 is a flow chart depicting a complete wireless charging session.

FIG. 14 is a flow chart depicting charger to vehicle interactions.

FIG. 15 shows an example rating period for a wireless charging customer with volumetric and demand charge components.

FIG. 16 is an overhead view of a charging station having multiple chargers capable of serving multiple vehicles concurrently.

FIG. 17 geographically shows the ability to use strategic opportunity charging to manage the utility demand charges.

FIG. 18 illustrates the example of single electric bus serving a single bus route.

FIG. 19 illustrates the example of multiple electric buses serving a single bus route.

FIG. 20 illustrates the example of multiple electric buses serving multiple bus routes with shared opportunity charger infrastructure.

FIG. 21 is a diagram depicting an example drayage yard using electric cargo transfer vehicles (not shown) with strategic wireless opportunity charging.

FIG. 22 geographically depicts an electric delivery vehicle route using strategic opportunity charging to minimize cost of travel.

FIG. 23 is an exemplary high-level functional diagram for power flow through and conversion by a bidirectional wireless power transfer (WPT) system that may be used for electrical arbitrage in a sample configuration.

FIG. 24 is a diagram depicting a simplified example configuration for enabling electrical arbitrage using reverse metering at a WPT charging station in a sample configuration.

FIG. 25 is a diagram of a system for managing a Charging as a Service (CaaS) system at the functional element level in a sample configuration.

FIG. 26 is a diagram illustrating a hybrid depot for charging and discharging of parked fleet vehicles in a sample configuration.

FIG. 27 is a diagram of a system for enabling electrical power arbitrage including elements shown as functional entities that may be run on distinct or distributed processing hardware and data storage in a sample configuration.

FIG. 28 graphically depicts the ability of an individual EV (e.g., a transit bus on a set route with a set schedule) to be used to store, convey, and discharge electrical power using a conservative charging strategy.

FIG. 29 is a diagram depicting a battery pack with ranges and thresholds in a sample configuration.

FIG. 30 is a flow chart depicting the control logic for charging and discharging from battery packs in a sample configuration.

FIG. 31 is a flow chart depicting the operational flow for controlling the charging and discharging from an in-service EV (e.g., a transit bus on the set schedule on a set route with estimated operational charging levels and estimated power consumption per route segment) in a sample configuration.

FIG. 32 graphically depicts the ability of an EV transit fleet (e.g., multiple buses serving set routes, each with a set schedule) to be used to store, convey, and discharge electrical power.

FIG. 33 shows an overhead view of an exemplary electric vehicle depot.

FIG. 34 is a state diagram of the operation of the exemplary electric vehicle depot of FIG. 33 in a sample configuration.

### DETAILED DESCRIPTION OF THE PREFERRED EMBODIMENTS

Strategic Opportunity Wireless Charging allows for increased deployment of electric transit vehicles without range or time limitations. Electric buses have zero tailpipe emissions, are quieter, and with Strategic Opportunity Wireless Charging can function without being taken off-line, or off-route, for refueling or recharging. EV transit vehicles are key to cleaner urban air, reduced traffic noise, and decarbonization. Strategic Wireless Opportunity is key to mass adoption and eventual automation of transit.

Electric Vehicles (EV) use electric traction motors and batteries in place of internal combustion engines and chemical fuels. EV is used here for both battery electric vehicles (BEV) and the various hybrid battery and internal combustion engine vehicles (HBEV). Batteries or Battery Packs nominally include rechargeable chemical batteries, but also could include one or more of a capacitor bank, a reversable fuel cell, a solid-state battery or a hybrid combination of the aforementioned. Improvements in energy storage technology (e.g., solid state batteries, hybrid battery and ultra-capacitors) can also be used to take advantage of quick opportunity charging using high power wireless power transfer (WPT).

In a typical example, an EV battery pack is made up of electrochemical battery cells. The longevity of the commonly used rechargeable Lithium-Ion battery cell is commonly quoted at 300 to 500 charge cycles. One charge cycle is the period of use from fully charged, to fully discharged, and then back to fully recharged again.

These rechargeable Lithium-Ion batteries have a limited life and will gradually lose their capacity to hold a charge. This loss of capacity (battery aging) is irreversible. As the battery loses capacity, the length of time it will power the bus is reduced, resulting in more a limited travel range, and run time.

Much has been written about the ability of wireless opportunity charging to reduce the size of the required battery and extend the range of electric vehicles. The ability of strategic wireless opportunity charging to preserve Lithium ion battery lifespan by keeping the rechargeable battery charge level between high and low state of charge (SoC) thresholds has been demonstrated in the field to extend battery lifespans. The charge rate and the battery temperature before charging and battery temperature during charging are also considerations in Lithium-Ion battery lifespans. Solid State batteries that can be charged and discharged 1000's to 10,000 times can still benefit from controlled charging levels, charging rates, and battery temperature considerations. In mixed fleets, some EVs may contain Lithium-Ion batteries and other solid state batteries (in some cases, the same EV may have multiple battery technologies). Such mixed fleets would benefit from the individualization of EV charging and performance data for modeling and machine learning.

Wireless opportunity charging describes how electric vehicles take advantage of wireless chargers deployed in their service or along their route. Since opportunity-charged EVs do not have “dead-head” time heading back to a depot or garage to charge, both time and battery charge can be saved for use in serving the route.

Opportunity charging allows for use of smaller batteries in EVs with resulting lowered weight and beneficially longer range or greater cargo capacity at range.

Opportunity charging also can be used to maintain the battery SoC between upper and lower thresholds to increase the longevity of the battery. An EVs battery pack can have a high cost of replacement and an increase in battery lifespan can lower total cost of distance (TCD).

Opportunity charging allows increased safety and comfort for drivers since there is no need to leave the vehicle at night or in inclement weather conditions as a plug-in charger with wires that require connection. Automatic opportunity charging also enables persons with physical disabilities to use electric vehicle charging.

In the following illustrative examples, electrically powered buses serving short to medium distance routes as part of a publicly pre-scheduled bus service local or regional network are referred to as ‘transit buses.’ For a transit bus, a terminal, or terminus, is where a transit route starts or ends and where drivers may dismount briefly or be exchanged. A terminal may also include a stop where passengers board and alight from vehicles. A bus depot is a terminal that includes maintenance and vehicle storage facilities. A stop is any transit stop where passengers may board and disembark from the transit vehicles.

For the transit bus (and indeed for any vehicle using the strategic opportunity charging protocols and system), first party data is defined as sent from sensors mounted on the EV. Second party data is defined as sent from other EVs or from sensors at instrumented stations (e.g., a charging station). Third party data is acquired from outside sources that are not the original collectors of that data. Third party data may be aggregated from multiple sources. Examples of third party data include maps, traffic conditions, and weather information.

All electric vehicles (EVs), which includes Battery EVs (BEV) and hybrids, have a range which can be estimated from the battery state of charge (SoC). The vehicle wear and tear, battery lifespan reduction, and price of power are all factors in the TCD (total cost per distance (mile or km)). When the price of power varies either over the route or over the service day, then an additional, variable factor of cost per watt becomes a factor in TCD.

A fleet management system, as defined herein, can include fleet energy management with each vehicle using radio data links to report sensor data and coordinate charging operations with the dispatch office controller. This coordination and information awareness extends over the opportunity charging capability as distributed over space (geographically and by travel route) and over time to reduce total fleet operating costs.

Multiple buses, geographically distributed charger sites, charger sites collocated chargers with high-use businesses or locations, and use of a mix of private and public usage charging sites are all contemplated and used to reduce the total cost of distance for individual EVs and for fleets of EVs via the fleet management system.

The collection of, communication of, storage of, monitoring of, and analysis of environmental, vehicle, charger, and charging session data over a single EV or over a fleet or multiple fleet of electric vehicles can be used both to enhance or optimize existing services as well as deliver new services based on analysis of the collected data. Use of historical data can be used to make better estimates for specific routes, vehicles, and drivers.

One such service is reduction in total cost of travel. Use of collected data can be used to guarantee all vehicles in an EV transit fleet complete service routes at a minimal cost by optimizing charging for individual EVs as well as for the entire fleet. This cost minimization is achieved with near-real-time data, models populated using past collected data, and knowledge of energy costs and of chargers located in different geographic areas with potentially limited power for charging available at each charger site or station.

The fleet management application used for cost minimization may optimize cost of travel for a single EV or for an entire fleet. Using individual EVs cost optimization as a goal, each EV may be optimized for potential local minimum cost of travel based on predictions using data collected from the fleet or from multiple fleets.

Using a fleet level goal, fleet optimization is designed for a global minimum total cost which might be different than the local optimization algorithm designed for minimization of cost for an EV bus. Trade-offs in the fleet management application modeling may accept charging of selected EVs in the fleet at higher cost of power over a first time period to gain a better overall outcome of the system instead of charging of those vehicles during a second time period when the cost of charging is lower to achieve an overall lower cost for the fleet or to manage power resources to minimize impact to the utility grid when charging.

Efficiency is the ability to do something or produce something without wasting materials, time, or energy. In the case of transit electric vehicle's efficiency may include electricity usage versus EV range, vehicle cost, and/or extension of battery pack lifespan dependent on the scenario.

The trove of 1^{st}, 2^{nd}, and 3^{rd} party data collected or otherwise obtained is well suited to both statistical analysis and machine learning (ML) techniques. Statistical analysis can be used to determine trends, patterns, and relationships (both causal and correlative) using the labeled quantitative and categorical data. Since the data is well-labeled, supervised learning algorithms for ML are well suited to be used when a specific goal or optimization is desired. In some cases, the data can be used with an unsupervised learning algorithm to cluster data and identify patterns, associations, or anomalies from the data.

Systems and methods described herein further provide electricity arbitrage using at least one Electric Vehicle (EV) that follows a prescribed route having a plurality of bi-directional chargers including, for example, a wireless power transfer (WPT) charger. A charging as a service (CaaS) management system receives EV data and at least one charging schedule for the prescribed route and charger data for respective bi-directional chargers along the prescribed route, and when an EV requests a charge from a bi-directional charger of the plurality of chargers, the CaaS determines whether the EV has excess charge beyond that needed to complete the prescribed route. When the EV has excess charge beyond that needed to complete the prescribed route, the CaaS instructs the EV to discharge electricity into the bi-directional charger of the plurality of chargers. On the other hand, when the EV does not have excess charge beyond that needed to complete the prescribed route, the CaaS instructs the bi-directional charger to charge the EV according to a charging plan.

In certain configurations, the bi-directional charger is located at a transit charging station for EVs that is connected to a local microgrid that provides electricity to the bi-directional charger from a local power generator when the EV does not have excess charge beyond that needed to complete the prescribed route and receives electricity from the EV for storage in local power storage when the EV has excess charge beyond that needed to complete the prescribed route. A reserve EV located at the transit charging station may be used as the local power storage and/or as the local power generator.

The CaaS may include at least one processor that executes instructions to use trained machine learning to generate at least one predictive model for performing route modeling based on historical EV data and prescribed route data and for managing charge availability of the plurality of chargers. The at least one processor of the CaaS may further executes instructions to receive electricity rate data for at least two bi-directional chargers along the prescribed route, calculate electricity pricing at the at least two bi-directional chargers along the prescribed route, and when a first of the at least two bi-directional chargers has a lower electricity cost than another of the at least two bi-directional chargers along the prescribed route, instruct the bi-directional charger to charge the EV to a charge level greater than a charge level forecast by the at least one predictive model. The at least one processor of the CaaS may further execute instructions to instruct the EV to discharge electrical charge to another of the at least two bi-directional chargers along the prescribed route when the EV arrives at the another of the at least two bi-directional chargers.

In other configurations, the at least one processor of the CaaS may execute instructions to receive electricity rate data for a bi-directional charger along the prescribed route, calculate electricity pricing at the bi-directional charger along the prescribed route for different times of day, and when the EV has excess charge beyond that needed to complete the prescribed route, instruct the EV to discharge electricity at the bi-directional charger when a cost of electricity at a time of charging is higher than a cost of electricity during a previous charging session. The at least one processor of the CaaS may further execute instructions to send a message to an electrical utility to coordinate supply of electrical power from the EV to a utility grid based on at least one of electrical demand, electrical ramp-up, or electricity price, and to coordinate storing of electrical power in the EV based on at least one of electrical power supply of the utility grid or price.

In other configurations, the at least one processor of the CaaS may further execute instructions to establish a cost threshold for electricity. Then, when the EV requests a charge from the bi-directional charger of the plurality of chargers, the at least one processor of the CaaS may determine whether a cost for electricity at the bi-directional charger is below the cost threshold, and when the cost for electricity at the bi-directional charger is below the cost threshold, instruct the bi-directional charger to charge the EV. On the other hand, when the at least one processor of the CaaS executes instructions to determine that a cost for electricity at the bi-directional charger is above the cost threshold and to determine that the EV has excess charge beyond that needed to complete the prescribed route, the CaaS instructs the EV to discharge electricity into the bi-directional charger.

In still other configurations, the at least one processor of the CaaS may further execute instructions to determine which charger of the at least one additional bi-directional charger along the prescribed route has a lower electricity cost at an anticipated time of charging, and to instruct the bi-directional charger having the lower electricity cost to charge the EV when the EV does not have excess charge beyond that needed to complete the prescribed route but has enough charge to reach at least one additional bi-directional charger along the prescribed route.

The at least one processor of the CaaS also may execute instructions to calculate the charging plan based on based on a total cost per distance (TCD) of travel over each of a plurality of route segments between the plurality of bi-directional chargers along the prescribed route, telemetry data received from the EV, and the charger data.

The at least one processor of the CaaS also may execute instructions to schedule charging at least one EV of a fleet of EVs or discharge of electrical power from the at least one EV of the fleet of EVs to a utility grid based on a cost of electrical power relative to a cost threshold and an electricity demand curve for the fleet of EVs at different times of day.

A detailed description of illustrative embodiments is described below with reference to FIGS. 1-34. Although this description provides a detailed description of possible implementations, it should be noted that these details are intended to be exemplary and in no way delimit the scope of the inventive subject matter.

### FIG. 1

FIG. 1 graphically depicts examples of EV range versus battery SoC from a single charge. The x-axis shows the range 101 while the y-axis shows the SoC 102 with the starting point of 103. In this example, simple linear models of travel are used to illustrate the concepts.

In a first example, the EV starts with a starting point SoC 103 (e.g., 100% SoC). As the EV travels 104 its SoC drops until it reaches 0% SoC at range 107.

In a second example, the EV starts with a starting point SoC 103 (e.g., 100% SoC). As the EV travels 105 its SoC drops until it reaches 0% SoC at range 108.

In a third example, the EV starts with a starting point SoC 103 (e.g., 100% SoC). As the EV travels 106 its SoC drops until it reaches 0% SoC at range 109.

The factors in determining EV range 107, 108, 109 can include vehicle characteristics, battery pack characteristics, environmental factors, load carried, terrain traversed, and driver abilities.

Vehicle characteristics include the make, model, manufacturer, age, mileage, and state of repair of the vehicle. Tire condition and tire selection are also considerations. Aerodynamics (air drag) is considered a vehicle characteristic.

Battery pack characteristics include make, model, manufacturer, capacity, battery aging (both time-wise and accelerated aging due to battery cycling), past battery usage and past inter-journey battery storage SoC. Data from sensors for the monitoring of the temperature of individual battery cells and the voltage levels of individual battery cells are expected to be available near-continuously via the vehicle's Battery Management System (BMS). The BMS provides oversight and management of the EV's battery pack. The battery pack nominally consists of an array of battery cells, configured and interconnected to deliver the need voltage and current needed. The BMS monitors the battery pack sensors (e.g., for current, voltage, temperature) and communicates with EV electrical subsystems and external chargers (such as a WPT charger). The BMS maintains the battery pack operational profile and protects against over-discharge, over-heating, and over-charging. The BMS may also optimize battery performance and lifespan by controlling the charging rate and SoC.

Environmental factors include weather, air temperature, and air pressure. The air temperature not only affects the battery state of charge, but also the electrical load needed for interior climate control (heating and cooling) for passengers and/or cargo as well as the vehicle systems (e.g., cooling the battery pack). Day versus nighttime travel may also affect range. Weather conditions (e.g., rain, snow, winds) may also affect range versus SoC. Lighting, such as headlights, interior and exterior lighting place a variable load on the battery pack. In colder climes, especially when evening darkness requires additional safety lighting, the combined heating (for passengers and the battery pack) and lighting loads can require a substantial fraction of the battery capacity, necessitating additional power transfer (either longer charging times or charging at higher power). Battery SoC safety margins may also require recalibration to preserve battery lifespan.

Environmental factors are expected to be available from charger site sensors, vehicle mounted sensors, and via third parties such as public weather stations and feeds to the dispatch server.

Load carried, either passengers or cargo, affects power consumption over the route with heavier loads decreasing range versus SoC. Both rolling friction and acceleration are affected by load carried.

Terrain traversed includes inclination and declination of the route traveled as well as curves, speeds, stops, and traffic conditions. Traffic conditions may be collected from a third-party service via an application programming interface (API) at the dispatch server. Terrain may be a large factor in power consumption over a route segment since uphill slopes will require additional power to surmount while route segments with generally downhill slopes will both ease power consumption and may store additional power due to regenerative braking.

Driver abilities include the conservation of battery resources by traffic lane selection, smooth acceleration, and smooth deceleration (braking). “Driver” here includes use of automated driver assistance software packages and autonomous driving systems.

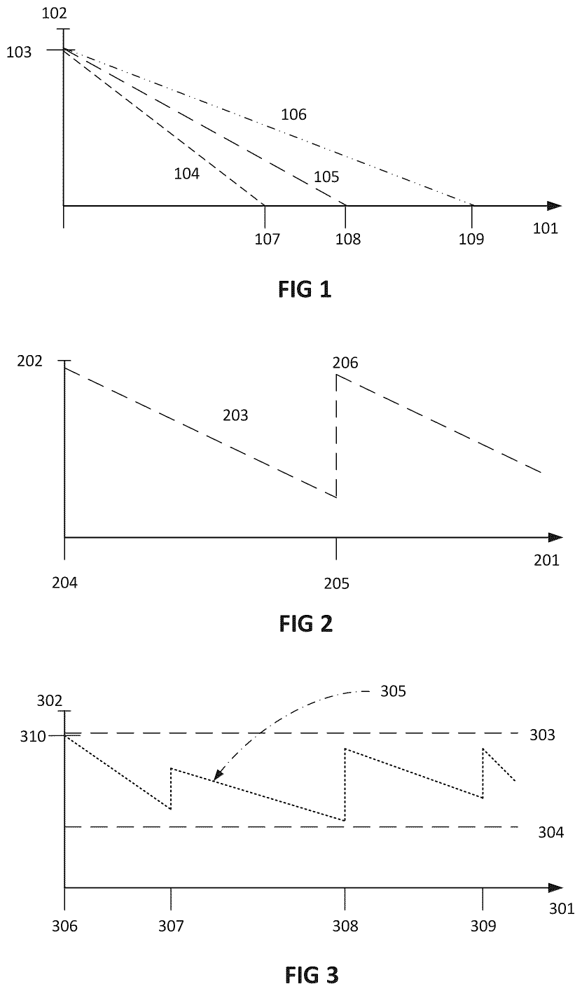

### FIG. 2

FIG. 2 graphically depicts an example of EV range extension by mid-route recharging. The x-axis shows the range 201 while the y-axis shows the SoC 202. In this example, a simple (linear) model of travel is used to illustrate the concept. In a first mid-range recharge example, the EV starts with a first SoC 202 at the start 204 of the travel. As the EV travels, the EV SoC level 203 decreases. At a charging point 205, the EV is recharged, and the recharged EV SoC 206 is then used to continue the journey over the range 201.

### FIG. 3

Wireless inductive charging allows for connectionless charging of EVs. Opportunity charging refers to charging an electric vehicle for short periods (and for smaller increments in SoC) throughout the journey. This partial recharging strategy contrasts with the recharging the EV all at once as shown in FIG. 2.

FIG. 3 graphically depicts an example of range extension and battery lifespan extension by strategic opportunity charging. The x-axis shows the range 301 while the y-axis shows the SoC 302. In this example, a simple (linear) model of travel is used to illustrate the concept. In this example of strategic static opportunity charging, the EV not only is partially recharged at every temporary stop 306, 307, 308, and 309, but the SoC is maintained between an upper SoC threshold 303 and a lower SoC threshold 304. The SoC profile 305 over the traveled route is shown varying in slope (in this simplified model) showing the differing consumption of power over route segments (i.e., between stops with opportunity chargers).

The upper 303 and lower 304 SoC thresholds are designed to increase the EV battery life. Only a single set of thresholds are shown here, but multi-level thresholds may be set for extending range while minimizing battery lifespan impact. Of course, the physical upper threshold 303 of 100% SoC and a lower threshold 304 of 0% are always available for range extension (e.g., for emergency use) at the expense of battery lifespan.

In the FIG. 3 example, the starting point SoC 310 is shown as just below the upper battery charge threshold 303. In some cases the starting point SoC 310 may be above (e.g., 100% SoC) or well below (e.g., 40%) if brought from long-term storage.

In one configuration, selecting upper and lower thresholds and using opportunity charging to maintain the state of charge between the selected thresholds, the useful life of a Lithium-Ion battery pack can be extended. Monitoring of temperature and voltage of individual batteries and varying charge rate to keep both below (and above) selected thresholds also can contribute to maximization of battery lifespan.

By knowing the vehicle battery operational thresholds, charger locations, route, time-of-day, current position, traffic level, and estimate time of arrival at the next charger, the decision to charge (and to what SoC level) can be made at or in advance of reaching an WPT opportunity charger. The cost of power from the electrical utility grid also may vary during the time of day or at the WPT charger location.

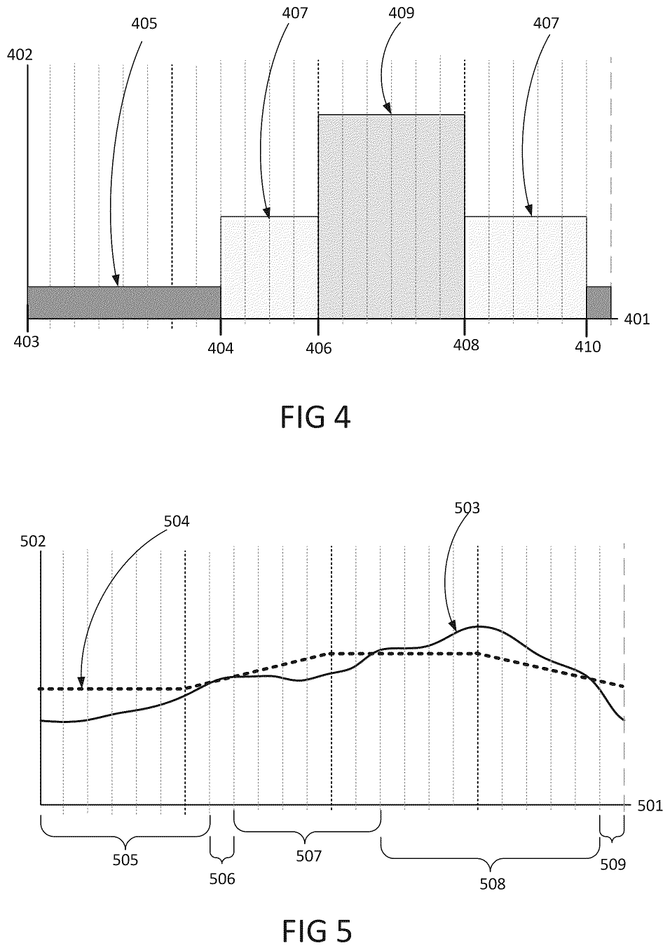

### FIG. 4

Time of Use (TOU) electric rates are a billing arrangement in which the price of electricity changes based on the time of day. TOU rates respond to electricity availability, with more expensive during peak hours demand hours and less expensive during the hours of low demand. These rates are typically static for a time period (week, month, season) to respond to changes in demand.

FIG. 4 graphically depicts the price of power over a 24-hour time period in an example. In FIG. 4, the X-axis 401 is the 24-hour day marked in 1 hour segments. The Y-axis 402 shows the price of power for each hour segment. In this illustrative example, starting at midnight 403 on the X-axis 401 and continuing to 8 am 404, the electric utility has the price set to “off-peak” 405. Between 8 am 404 and noon 406, rising demand has the utility pricing set to “mid-peak” or “shoulder” 407. Between noon 406 and 6 pm 408 the utility pricing is set to “peak” 409 during the hours of highest demand. After 6 pm 408 and until 11 pm 410, the decreasing demand has the utility pricing set to “mid-peak” 407. After 11 pm 410, the rates drop back to “off-peak” 405. As can be seen in FIG. 4, the pricing varies with rising and falling demand.

EV charging (per watt) will be cheapest during off-peak hours, most expensive during peak hours. Selective charging of the EV during the day (both the time-of-charge, and level of charging at a charging session) to minimize costs can be accomplished.

Not shown are the weekend TOU rates which can be different from the work-week (e.g., Monday-through-Friday). In some regions, the weekend rate is set to “off-peak.”

### FIG. 5

In some regions and markets, competitive utilities may be available. As shown in FIG. 5, first and second utilities share the same geographical market with a deployed WPT system and offer different electric rates based on the hourly time-of-day and power generation capabilities and capacities. In FIG. 5, the X-axis 501 is the 24-hour day marked in 1 hour segments. The Y-axis 502 shows the price of power for each hour segment. In this illustrative example, in the first period 505 (midnight to 7 am), the first utility market rates 503 are cheaper. During the second period 506 (7 am-8 am), the rates for both utilities 503 and 504 are roughly equal. The third period 507 (8 am-2 pm) has the first utility rate 503 cheaper. During the fourth period 508 (2 pm-11 pm), the second utility rates 504 are advantageous. Finally, in a fifth period 509 (11 pm-midnight) the first utility offered rates 503 are again preferred.

By selecting service from the cheaper utility during the charging time, the cost of power for EV charging can be reduced. Managing the charging time, duration, and charge level can increase these savings by minimizing charging during the higher cost of power times of day.

Since demand, availability, and cost of electric power may vary considerably on a day-to-day or even hour-to-hour, these all factor into the decision to charge. Information on electric rates can be obtained by from the terms of prior contracts with the local utility, from a data feed from the local the electricity exchange, or the public market spot price for electricity when multiple suppliers feed utility. Examples of electricity markets include the Day-Ahead Energy Market and the Real-Time Energy Market.

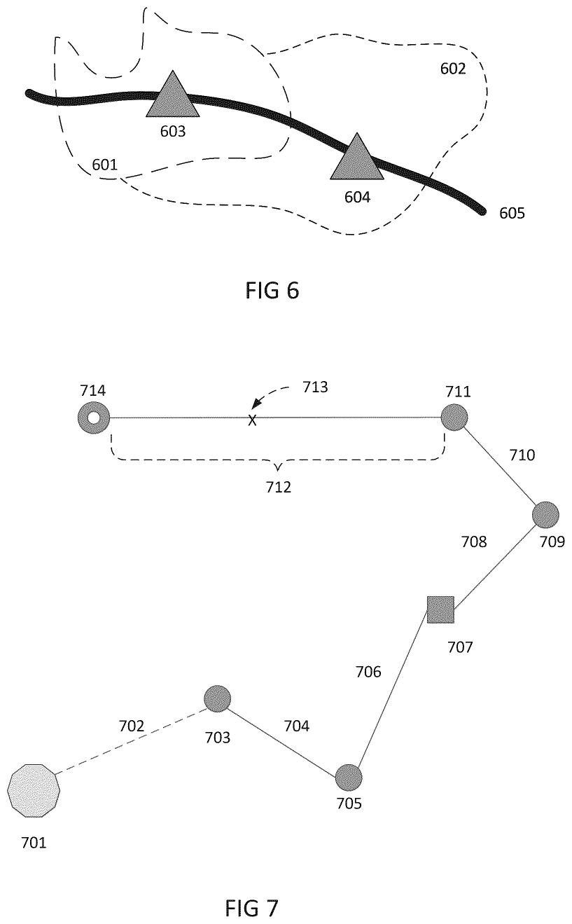

### FIG. 6

### Utility Service Areas

Charger locations may place consecutive chargers on a particular route in different utility service areas where pricing information from multiple sources may need to be obtained and considered on the charging decision. In cases where the charger(s) are owned by a third party (one other than the utility and fleet operator), the price of electricity may need to be obtained from the third party for the estimated charging time.

FIG. 6 depicts an example where two regions 601 and 602 are traversed by an EV route 605. In this example, each region 601 and 602 is served by a different utility, each with different pricing. The WPT opportunity chargers 603 and 604 thus can have a differing cost of power. Using differing charging duration and power levels at each WPT charger 603 and 604 at specific times of day, the total cost of charging for the route can be optimized.

### FIG. 7

FIG. 7 geographically depicts an exemplary distribution of wireless chargers along a bus route. While recharging may be done at inter-route transit stations or inter-connection stations (e.g., at rail or airport terminals) with longer hold-over times, deployments can include recharge stops located advantageously (e.g., at ranges where the predicted battery SoC is predicted to cross a lower threshold).

### Predictive Modeling

By obtaining the pricing at multiple chargers along the route at the multiple estimated times of arrival, a cost of travel profile for the route may be generated at the start of the day. Based on the upper and lower SoC battery thresholds, a cost optimization can be calculated and recalculated as needed if the original route is departed from or the model fails to predict accurate SoC values. Data used to populate the cost optimization model may include training data from the current route, the current fleet, or other fleets using the same or similar electric vehicles. In some cases, a substantial cost difference in charging either from one location to another, or from one time to another can engage a second set of battery SoC thresholds.

Recalculation of the modeled cost of travel can include deviances from the schedule both for early arrivals and late arrivals. In cases of early arrival, additional charging time is available for use and may result in a lowered offered charging current. In cases of late arrivals, a higher charging current may be made available to shorten charging time over the potentially foreshortened stop duration.

A system to enable continuous operation of electric fleet vehicles by using on-route wireless charging is described below. Vehicle SoC is kept at optimal levels to promote battery health and longevity while also taking into account the price of electricity to optimize the cost to operate the vehicle.

Sensor data is collected repeatedly throughout operation during route charging sessions to facilitate dynamic charging models that take into account electric vehicle type (make, model, year), environmental factors (e.g., weather, traffic conditions), driver behavior and drive-train and battery pack health that affect the performance of wireless charging and the operation of the vehicle.

Data collected across EV transit bus fleets is used to automatically optimize models to increase or decrease charging power based on these factors to enable vehicles to remain in operation indefinitely while also maintaining optimal SoC across the fleet at the lowest cost possible in terms of both battery lifespan and cost of electricity.

For each electric vehicle type (i.e., make, model, manufacturer, year, battery pack) or EV class, at least one minimum SoC threshold is established. The minimum SoC is dynamic and may be based on: a) minimum SoC to limit battery damage (lifespan reduction), b) minimum SoC required to reach the next two charging stations in a route, c) minimum SoC need to complete a route without charging, d) minimum SoC calculated to abort the route and to reach the depot, e) SoC charge when the route is started, and f) a manually set SoC threshold.

In a minimum power regime, the EV is only allowed to charge to the predictive value of SoC for each stop with a wireless charger. This minimum power regime can be altered based on the estimated price of electricity at WPT chargers on the route.

As the recharging network grows and higher power wireless charging service is deployed, wireless opportunity chargers may be placed at more geographic positions where even brief stops can be used for opportunity charging or where charging lanes equipped with dynamic inductive chargers are deployed. Note that both the static and dynamic charging EVs may make use of the near-field communications such as detailed in U.S. Pat. No. 10,135,496; “Near field, full duplex data link for use in static and dynamic resonant induction wireless charging.”

FIG. 7 displays one exemplary transit route. The depot 701 is used to house and service the electric transit bus when not in service. The depot 701 may be part of a terminal and passengers may board before departure. Passengers may embark and disembark at each pre-planned stop. Other stops may be introduced ad hoc for passengers to disembark. A first route segment 702 is traveled to bring the bus to the first stop 703 where passengers may embark and disembark. The second route segment 704 brings the bus to the second stop 705 where passengers may embark and disembark. The third route segment 706 brings the bus to the first transfer station 707 where passengers may embark and disembark to travel on another, crossing transit route. The driver may also use this site 707 and opportunity to take a mandated break. Traveling the fourth route segment 708 brings the bus to the fifth stop 709 where passengers may embark and disembark. Traveling the fifth route segment 710 brings the bus to the sixth stop 711 where passengers may embark and disembark. Traveling the sixth route segment 712 brings the bus to the bus station 714 which is the end of route in this example. In this example, the longest route segment 712 contains a charger stop 713 where the bus may briefly stop for charging. The charger stop 713 alternately may be a dynamic opportunity charger where the bus need only drive over the charger equipped road surface without need to stop.

At any of the planned stops 703, 705, 707, 709, 711, and 713, wireless opportunity chargers may be installed. Additional Charger sites (not shown) may be deployed between stops to increase range while keeping SoC within the SoC threshold boundaries.

For electric transit vehicles (e.g., buses), opportunity charging requires charging sites to be located on or near the driven routes. Charger placement is initially accomplished by mapping and modeling (using data either collected (via test drives), modeled, or from similar routes and vehicles), of routes with chargers placed at depots and stops (or in some case between stops) where sufficient power may be obtained. For cost reduction, chargers will normally be placed at a subset of stops.

Once the transit system (with attendant data collection, transmission, and analysis) is operational, the collected data may be used to determine if 1) additional charger(s) are required, 2) fewer chargers are needed, or 3) chargers may be decommissioned and moved to another site to better serve the transit fleet in meeting total cost of travel goals.

Where the charger and data infrastructure is shared among multiple fleets, use of travel data from the multiple fleets can be used to rebalance the charger infrastructure to adjust to newly deployed EV transit vehicles, to adjust to changing vehicular traffic patterns, and changes in ridership and routes.

When multiple fleets share the opportunity charging infrastructure, ownership of chargers and payment of charging costs may be accumulated and negotiated between the fleets. In some scenarios, a local or regional authority will own, operate, and service the wireless charger network and ancillary communications and data systems and will apportion cost to the served fleets.

In some cases, wireless chargers owned and operated by non-fleet commercial or governmental operators can be used to supplement the transit wireless charger network.

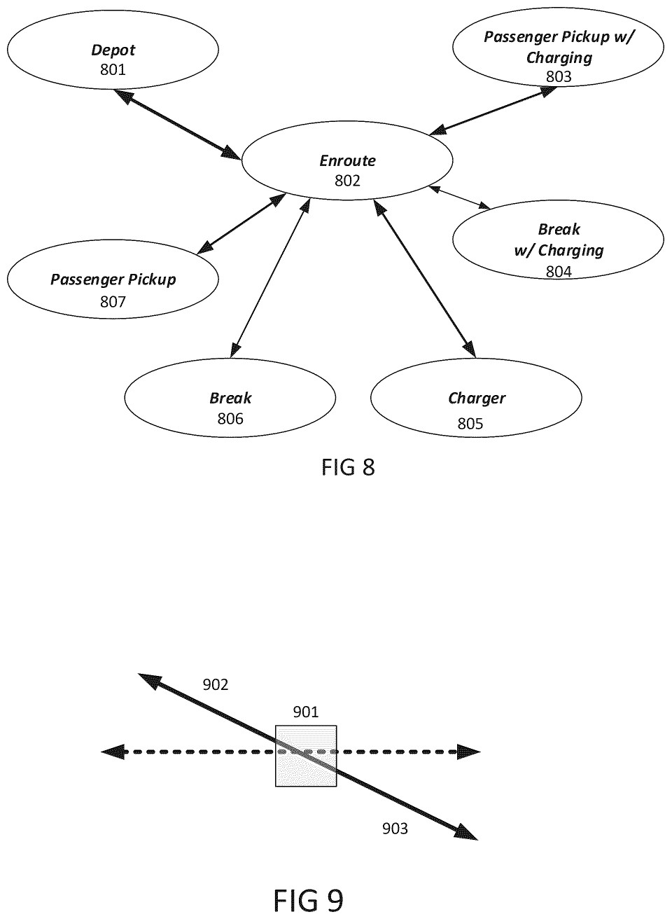

### FIG. 8

FIG. 8 is a diagram depicting an example state machine for a transit bus with wireless charging.

The state machine of FIG. 8 illustrates the data collected at different times and events along the electric vehicle route.

The Depot State 801 is encountered at least twice in this example. Once on departure and once on end-of-day. Additional encounters may occur, for example, due to driver shift changes or necessary vehicle maintenance.

At departure from the depot, the bus systems are fully charged (to SoC upper threshold), preheated, cooled, or air-conditioned as necessary for the start-of-day. The vehicle characteristics (e.g., make, model, year) and the driver (or driver software) identity are recorded.

The onboard Data Store includes departure (current) time, the battery state (SoC) and SoC Thresholds/Limits, vehicle empty weight, the current location and route. For the planned route, the planned stops (locations) for passengers and chargers are established. For each charger on the route, the rate schedule and the spot rates for electricity are known. The theoretical SoC used for each route segment is predicted using modeling based on past histogram data for the route, a similar route, or a simplified exemplary route model. The calendar and scheduled events along the route (and detours) are known and are considered during route pre-planning and modeling.

The Enroute State 802 is expected to be the most common state and encompasses all travel. During the Enroute State 802, the data store accumulates the current time, current position, SoC, passenger count, traffic conditions and vehicle speed.

The data store may use a periodic or event driven update to accumulate and store vehicle and route data. Stored data is tagged with the time as well as the current location and route segment. The odometer mileage may be used as a fallback positioning for when precise location is not available. Data may be uploaded via wireless connection (e.g., cellular or satellite modems) to the dispatch office.

For Passenger Pickup with charging 803, the data store is updated with the start time and end time of the stop. Using the passenger on/off counter (or the bus weight change as a proxy), the total number of passengers served, the current number of passengers, and the embarking and disembarking passenger counts are updated. With charging taking place, the charging current, start and end SoC is recorded. The charger may send additional charging session data via its communication link that includes charger status (and vehicle wireless power receiver status) as well as details concerning the inductive charging energy transfer (e.g., coupling, frequency, equipment temperature(s)).

Route information may be updated via the charging site communications system or the bus's radio communications system. Route related information includes distance to next stop, type of stop, SoC thresholds and limits, charger status and availability at next stop with a charger, and charger status for at least all chargers along the route.

For a Driver Break with charging 804, the data store is updated with the start time and end time of the stop. Using the passenger on/off counter (or the bus weight change as a proxy), the total number of passengers served, the current number of passengers, and the embarking and disembarking passenger counts are updated. With charging taking place, the charging current, start and end SoC is recorded. The charger may send additional charging session data via its communication link that includes charger status (and vehicle wireless power receiver status) as well as details concerning the inductive charging energy transfer (e.g., coupling, frequency, equipment temperature(s)).

Route information may be updated via the charging site communications system or the bus's radio communications system. Route related information includes distance to next stop, type of stop, predicted SoC, etc.

For a Charger Stop 805, the data store is updated with the start time and end time of the stop. No passengers are expected to board or disembark at a charger stop 805. With charging taking place, the charging current, start and end SoC is recorded. The charger may send additional charging session data via its communication link that includes charger status (and vehicle wireless power receiver status) as well as details concerning the inductive charging energy transfer (e.g., coupling, frequency, equipment temperature(s)).

During the Charging Stop 805, route information may be updated via the charging site communications system or the bus's radio communications system. Route related information includes distance to next stop, type of stop, predicted SoC, etc.

For a Driver Break 806, the data store is updated with the start time and end time of the stop. Using the passenger on/off counter (or the bus weight change as a proxy), the total number of passengers served, the current number of passengers, and the embarking and disembarking passenger counts are updated. With no charging taking place at a Driver Break 806, the start and end SoC is recorded. Route information may also be updated via the bus's radio communications system. Route related information includes distance to next stop, type of stop, predicted SoC, etc.

For a Passenger Pickup (without Charging) 807, the data store is updated with the start time and end time of the stop. Using the passenger on/off counter (or the bus weight change as a proxy), the total number of passengers served, the current number of passengers, and the embarking and disembarking passenger counts are updated. With no charging taking place, the start and end SoC is recorded.

At a Passenger Pickup (without Charging) 807, route information may be updated via the bus's radio communications system. Route related information includes distance to next stop, type of stop, SoC thresholds and limits, predicted end SoC, charger status and availability at next stop with a charger, and charger status for at least all chargers along the route.

### FIG. 9

FIG. 9 diagrammatically illustrates the case where a single charger 901 is used to service first 902 and second 903 transit routes and thus service multiple EVs that service those routes 902 and 903.

In some cases, the power available for opportunity charging at a charger may be exceeded by the amount of power requested or the number of vehicles that need charging, or both. This includes allocation of chargers that match particular vehicle populations or chargers that support non-standard communications protocols or charging signaling.

Contention for scarce charging resources (power and/or chargers) occur for cross-route charging stations, such as shown in FIG. 9. Contention may also occur for third party operated charging stations, stations experiencing back-up due to in-transit delays, stations with chargers disabled, chargers in localities with electrical shortages, and in cases of emergency service preemption of chargers.

The contended charger resources also experience fluctuating energy prices over space (geographical) and time of day. Power distribution planning, and energy management via prediction from modeling of historical data can be used to administer and allocate the limited available power for use at each station or particular charger at the station.

In cross-route stations, such as in FIG. 9, serving two or more transit routes, arrival of transit vehicles may differ from the scheduled arrival and charging times.

With third party operated charging stations, time of vehicle arrival, the number of vehicles, the charging levels, the total charge demand, as well as the number of modular charging pads per charger and per vehicle (as described in U.S. patent application Ser. No. 17/646,844; “METHOD AND APPARATUS FOR THE SELECTIVE GUIDANCE OF VEHICLES TO A WIRELESS CHARGER”) may be considered even if a prioritization scheme and reservation system (as described in U.S. Pat. No. 11,817,722; “OPPORTUNITY CHARGING OF QUEUED ELECTRIC VEHICLES”) are fielded.

At charging stations experiencing back-up due to in-transit delays, a queuing scheme based on scheduled departure time and vehicle SoC can be implemented. Planning for stations with non-functional chargers have the additional layer of complexity in that a modular charger may soft-fail where a subset of the charger is still available for use.

In some cases, electrical power shortages may require power rationing. Vehicles may be assigned power priority based on SoC or a ranking system. Power priority may be serviced by supplying a higher charging rate than lower priority vehicles or suspending power to lower priority vehicles.

Where emergency or other high priority electric vehicles need charging, a preemption scheme may be provided where a currently charging vehicle has its charger commandeered, or the next available charger is held for the use of the preempting vehicle.

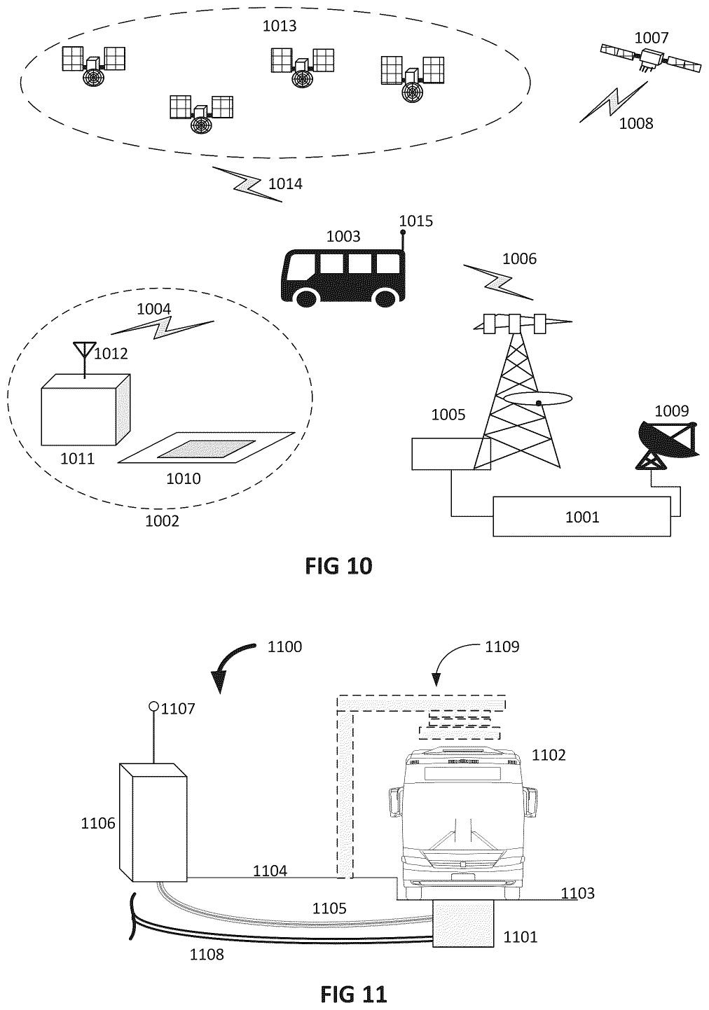

### FIG. 10

FIG. 10 depicts at a high level the communication paths available for data collection from an EV and from the WPT charger. Data collection is used for strategic opportunity charging pricing. Telemetry (including bi-directional telemetry) uses wired and wireless communications to transfer data and information between remote sources (including mobile sources and users) and distant destinations. Telemetry data streams between source and destination can consist of continuous, periodic, polled, or ad hoc transmissions of data. Telemetry includes the automatic measurement and wireless transmission of data from remote sources with the data collected routed to receiving equipment at a destination site (e.g., the dispatch server 1001) for monitoring, display, recording/storage, post processing, analyzation and trending.

The data store is part of database software with data management software (e.g., the IBM Maximo Enterprise Management System) running on processor hardware with a computer operating system with a large memory storage unit. The functions of security and multi-party access control are via the data management software. In some implementations, the dispatch server 1001 and associated data stores may be implemented as a virtual, hosted (e.g., cloud-based) system or as an on-premise hardware (with requisite processors, memory, and fault tolerant data storage) and software system, based on generic high-availability computing platforms sized to fit processing and storage needs, local to the dispatch office. The dispatch server may include (or has interfaces to) redundant, and potentially partitioned and federated, databases; and Geographical Information Systems (GIS). Interfaces to other third party information such as electricity pricing, traffic and weather information may be centralized at the dispatch server 1001.

A data store resides in the vehicle but uploads accumulated data to the dispatch server 1001. Uploads may be on request of the dispatch office, or a periodic or event driven (e.g., a WPT charging sessions starts) update. The EV is equipped with a navigation system (e.g., based on Navstar GPS, Galileo, GLONASS, BeiDou, Quasi-Zenith Satellite System (QZSS) (also known as Michibiki) or a local radio location beacons). The data store has access to the vehicle systems and battery management system (BMS) via local data links (e.g., a Controller Area Network (CAN) bus).

Data sources can include databases of historical data, models using recorded and near-real time data. Sources can also include near-real time data that may include sensor output from sensors including either electrical data (such as voltage, current, or state-of-charge) or physical data (such as temperature(s), pressure, mass).

Telemetry also can include data products such as location, passenger count, time stamps, data source identifiers, map updates, and route updates. In this application, the vehicle data store accumulates and may transmit collected electric vehicle related data on a near-continuous basis to the dispatch server 1001.

The dispatch server 1001 includes application specific software that includes a data management system, APIs for interfacing with both third-party information feeds (e.g., traffic, weather, public charger status) and communications interfaces for data originating from the charger site(s) 1002 and from EV(s) 1003. The charger site 1002 may use either wired (not shown) or a wireless radio interface 1004 for bi-directional communications. Depending on the installation, such wireless radio interfaces can use public or private cellular data networks 1005 using public or private band radio signals 1006. An alternative or supplemental wireless radio network may be supplied from satellites 1007 using established satellite communications band radio signals 1008. Satellite data receiver(s) 1009 may be used to deliver satellite communicated data to the dispatch server 1001.

Data may be both generated by and communicated via the wireless charger site 1002 to the EV 1003 and/or the dispatch server 1001. Each charger site 1002 has at least a wireless charger 1010 and ancillary equipment 1011 (shown here as an above grade cabinet but may be installed in an underground vault). The ancillary equipment 1011 may contain a wired or wireless backhaul (shown here as a radio antenna 1012 for a cellular radio connection 1004).

Route segments for a transit bus 1003 are pre-planned with set arrival and departure time for each geographically pre-determined site. The time and the route segment and odometer reading allows calculation of a rough level of location. More precise location for a vehicle 1003 is available using vehicle mounted navigation receiver(s) (not shown) for Global Navigation Satellite Systems 1013 (e.g., Navstar GPS, Galileo, GLONASS, BeiDou, Quasi-Zenith Satellite System (QZSS) (also known as Michibiki)) using satellite broadcast signals 1014. Other communications satellite constellations broadcasts (e.g., the carrier frequencies from the Starlink system (a high-speed, low-latency broadband internet carrier designed for remote and rural locations across the globe) can also be used for positioning.

Alternately, precise positioning can be obtained using geographically local radio location beacons (beacons have a known frequency, known bandwidth, known or broadcast transmitter location, and a transmitted identification (ID)) where deployed or available.

In the transit EV 1003, radio receivers and transceivers 1015 are used to receive the GNSS or local beacon positioning signals, to communicate via landside cellular networks, and potentially use Satellite communications systems for receiving and transmitting information.

The dispatch office and servers 1001, especially in a region with multiple fleets and shared or 3rd party wireless charging resources, can be owned or managed by a 3rd party, non-fleet, party (the host) offering charging as a service (CAAS). The Charging As A Service program removes the burden of ownership and maintenance from the charging EV fleets, with the host providing such things as turnkey wireless charging stations, the management software, communications infrastructure, 24/7 support, professional field maintenance for charger resources, as well as planning and modeling to deploy new chargers and revamp existing charger deployments when the need for a change in charger location or an increase (or reduction) of charger capacity is detected at any existing charger site.

### FIG. 11

An example wireless charger site 1100 is depicted in FIG. 11. A wireless charger 1101 for charging a transit vehicle 1102 is shown installed on level with the pavement 1103. A pedestrian area 1104 may be co-located if passengers embark or disembark at this portrayed site 1100. A conduit 1105 provides interconnection with the wireless charger for cooling lines from a cooling structure 1106 and for wired or optical communications lines (not shown) to the radio transceiver and antenna 1107.

The wireless charger 1101 provides radio communications between the wireless charger 1101 and the vehicle 1102. These communications may be as described in U.S. Pat. No. 10,135,496; “NEAR FIELD, FULL DUPLEX DATA LINK FOR USE IN STATIC AND DYNAMIC RESONANT INDUCTION WIRELESS CHARGING;” issued Nov. 20, 2018. Static inductive charging relies on the EV maintaining its position during charging to pair the primary and secondary coils. Dynamic inductive charging uses near-continuous series of primary coils (often buried in the road), often consisting of coils elongated in the direction of travel, to charge the secondary coil attached to a moving vehicle. Semi-dynamic charging uses the same primary and secondary coils as the static inductive charging system but expands the operational angles at which a secondary coil may be serviced and thus total charging time for each primary coil.

The wireless charger 1101 in this example configuration is powered via a wired DC connection 1108 to the local utility grid (not shown).

In some cases, a mechanical actuator system for connecting a physical wire can be used for opportunity charging. The pantograph system 1109 shown is one such alternative system using a physical connector.

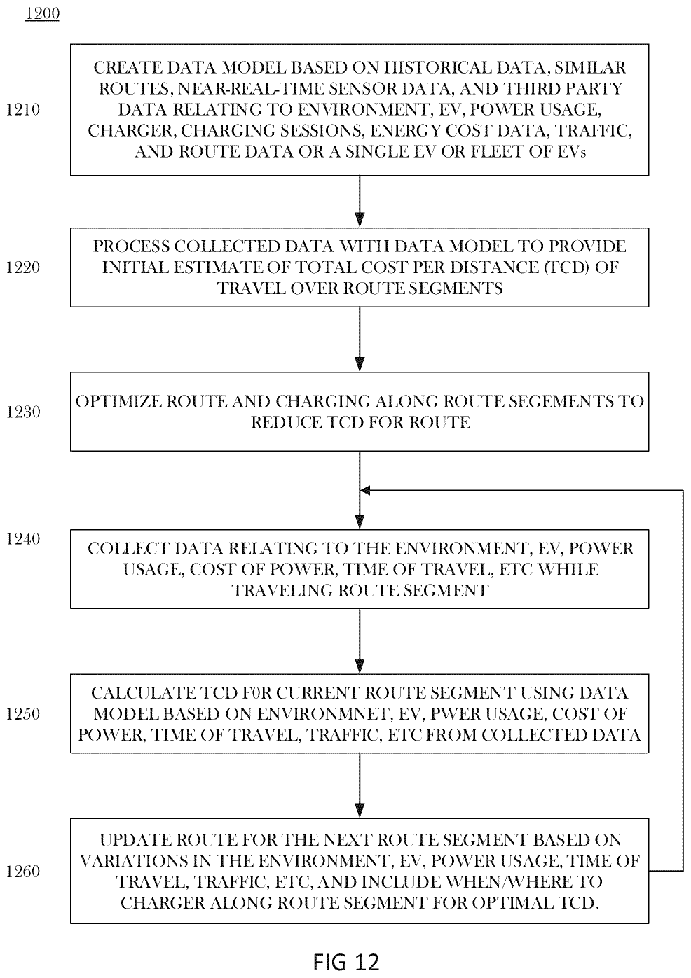

### FIG. 12

FIG. 12 is a flow chart of a sample method 1200 for strategic opportunity charging in an example configuration.

As illustrated, the method 1200 includes creation at 1210 of a model based on historical data, similar routes, near-real-time sensor data, and third-party data for use in creating optimal routes for EVs used in commercial and non-commercial settings. The collected data relates to the environment, EV characteristics, power usage, charger characteristics, charging sessions, energy cost data, traffic, and route data for a single EV or a fleet of EVs.

Once the data model has been created at 1210, the collected data is processed with the data model to provide an initial estimate of the total cost per distance (TCD) of travel over anticipated route segments at 1220.

The route and the charging along the route segments is optimized at 1230 to reduce the TCD over the route for the EV or the fleet of EVs.

The EV then starts along a route segment. The telemetry systems and third-party systems collect data relating to the environment, the EV, power usage, cost of power, time of travel, etc. in near-real-time as the EV travels along the route segment at 1240.

At the end of the current route segment, the TCD is calculated at 1250. The TCD is calculated using the data model based on the collected environment, EV, power usage, cost of power, time of travel, traffic, etc. data that has been collected as the EV traversed the route segment.

An updated estimate for the next route segment is calculated at 1260 based on variations in the environment, EV, power usage, cost of power, time of travel, traffic, etc. The updated estimate further includes when/where the EV should charge along the next route segment for optimal TCD using available chargers and the available duration of the stop.

The steps 1240-1260 are repeated for each route segment until the process is reset.

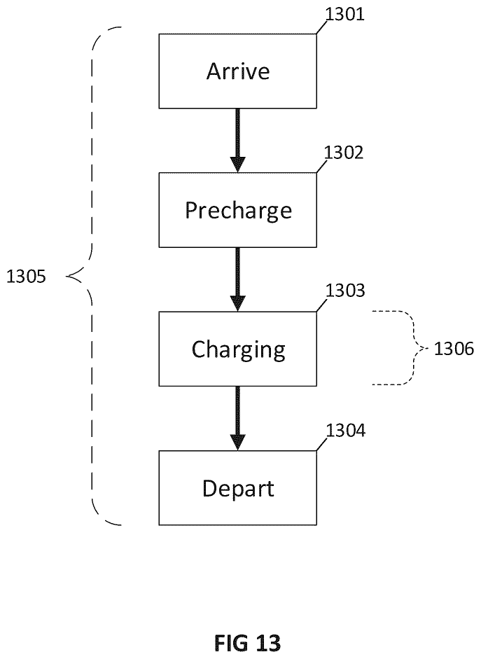

### FIG. 13

FIG. 13 graphically depicts at a high level the wireless charging operation at a time limited stop at a wireless charger. The EV first arrives 1301 with a first State of Charge (SoC) and is directed to a wireless charger. This direction can arrive via radio link but also via indicator lights, signage, or automated steering assistance (for examples see U.S. Pat. No. 10,040,360; “METHOD AND APPARATUS FOR THE ALIGNMENT OF VEHICLES PRIOR TO WIRELESS CHARGING INCLUDING A TRANSMISSION LINE THAT LEAKS A SIGNAL FOR ALIGNMENT” and U.S. patent application Ser. No. 17/646,844; “METHOD AND APPARATUS FOR THE SELECTIVE GUIDANCE OF VEHICLES TO A WIRELESS CHARGER”).

During Pre-charge 1302, the ground charger and the vehicle power receiver are tuned for efficient wireless transfer at the achieved alignment and air gap. Information is exchanged for authorization and billing via a radio connection. In the case of a modular ground charger, multiple frequencies and phases (see, for example, U.S. patent application Ser. No. 17/207,257; “MODULAR MAGNETIC FLUX CONTROL”) may be set.

During Charging 1303, the vehicle Battery Management System and the ground charger controller (not shown) negotiate the supplied current. The ground controller may set an initial maximum current supplied in accordance with the dispatch controller instructions (based on the data model) and then during charging alter the supplied current in accordance with new instructions.

Leaving the Charging Session, the EV departs 1304 the charging station with a new SoC.

In the transit bus example, the EV has set arrival and departure times and thus a preset total stop duration 1305. The Charging interval 1306 is a subset of the total stop duration 1305.

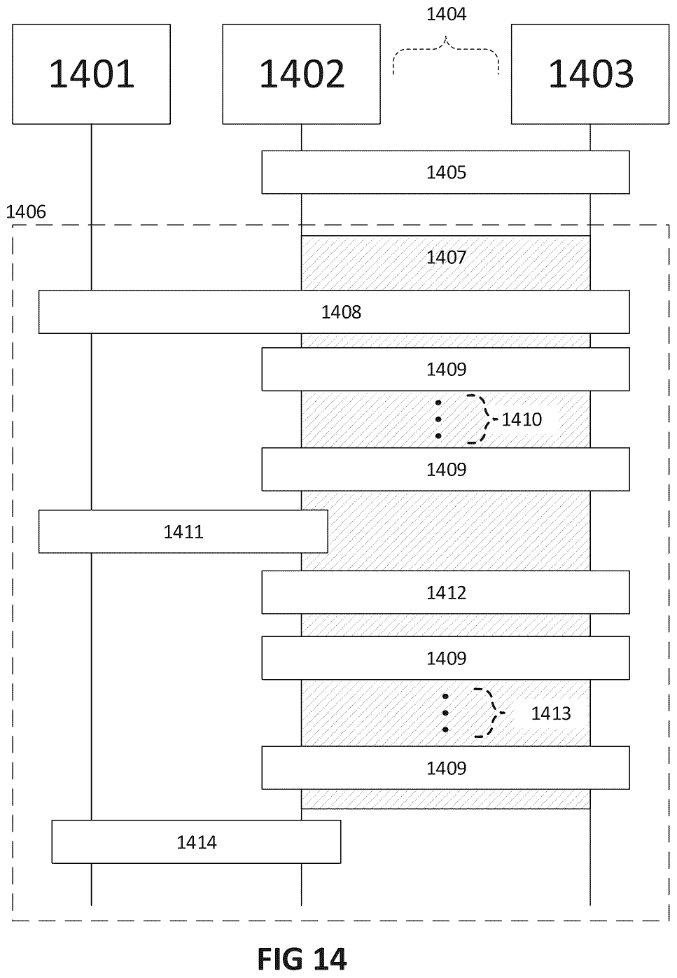

### FIG. 14

The charging manager 1401 could be an application running on the dispatch server 1001, or a local controller (such as the charging station server (first disclosed in U.S. Pat. No. 11,817,722; “OPPORTUNITY CHARGING OF QUEUED ELECTRIC VEHICLES”, the disclosure of which is incorporated herein by reference). The Charging station server contains the charging manager 1401 software to manage the electrical supplies (from the utility and local storage), the charging station's internal communication links (both bridging and routing) with the wireless charger(s) 1402, and interconnection to entities (servers, data repositories, cloud instantiations) external to the charging station. All messaging in this example is paired, with each origination having a confirmation response.

In the current example, the Ground Charger Assembly (GCA) 1402 includes a near field radio communications interface (as detailed in U.S. Pat. No. 11,121,740; “NEAR FIELD, FULL DUPLEX DATA LINK FOR RESONANT INDUCTION WIRELESS CHARGING”, the disclosure of which is incorporated herein by reference). The physically corresponding Vehicle Receiver Assembly (VRA) 1403 is present across the air gap 1404 for charging when using the near field radio communications interface. Alternative or supplemental wireless communications links based on wireless local area networks (W-LAN) technology (e.g., IEEE 802.11, Zigbee, Bluetooth) may also be used.

Before the Wireless Charging Session 1406 begins with the GCA 1402 and VRA 1403 exchanging messaging for authorization, mutual authentication (in this model neither the GCA 1402 nor the VRA 1403 is trusted), and billing. The battery management system (BMS) operations in the current example is included in the VRA 1403 functionality and pass-through messaging.

Standardized messaging for a wireless power transfer charging of Electric Vehicles (EVs) has been published by the International Engineering Consortium (IEC) as IEC 61980, parts 1, 2, and 3. More specifically, IEC 61980-3:2022; “ELECTRIC VEHICLE WIRELESS POWER TRANSFER (WPT) SYSTEMS-Part 3: Specific requirements for magnetic field wireless power transfer systems”, (published November 2022) can be useful for generalized illustration purposes as the supported use cases and messaging herein differs.

Immediately before charging, radio messaging 1405 may be exchanged to measure and assure alignment between the GCA 1402 and VRA 1403, to measure the magnetic gap, to determine the efficient magnetic transmission frequency (see U.S. patent application Ser. No. 17/643,764; “CHARGING FREQUENCY DETERMINATION FOR WIRELESS POWER TRANSFER” and included herein via reference), and to exchange capability and limits.

Once the preliminary messaging 1405 is over and the charging session 1406 begins, the VRA 1403 and GCA 1402 begin exchanging information messages 1407 that contains relevant GCA 1402 and VRA 1403 electrical, temperature, and/or radio sensor data and provides a periodic heartbeat. The information messaging 1407 can contain BMS supplied information on the battery pack voltage(s), temperature(s), and State of Charge. The information message streaming 1407 continues throughout the duration of the wireless power transfer (while the magnetic flux is being generated).

The VRA 1403 then begins the power request/response messaging 1408 via radio signaling over the air interface 1404, via the GCA 1402 and to the charging manager 1401. The power request may include a requested current level and the power response may include a granted current value. The power request may also include a preferred current level and a maximum current level, and the power response may include a granted current value at or below the requested value or maximum current level.

The GCA 1402 will message the VRA 1403 confirming the initial current level assignment 1409 and energize the charging signal. During the duration of the power transfer 1410, the heartbeat/telemetry 1407 messaging continues.

In this example, the charging manager 1401 sends the GCA 1402 involved in the charging session 1406 a Rating command 1411. The Rating Command 1411 includes a current level that may be above or below the initial current level (the current level can be zero, pausing or ending the charging session 1406 prematurely). The updated current level is passed to the VRA 1403 at 1412 before the charging signal is changed. The VRA 1403 acknowledges the updated current level in its response 1409 which can request the new maximum allowed current level or any current level below the updated current level.

For the second wireless power transfer duration 1413, the GCA 1402 provides magnetic signal to generate the new allowed current level in the VRA 1403. The EV, via the BMS and VRA 1403 will end the wireless power transfer by setting a requested current level to zero. The GCA 1402 will suspend the charging signal and inform the charging server 1401 via a termination notification 1414 that the session has ended. The GCA 1402 uses the termination notification 1414 to pass collected time(s), sensor, and performance data to the charging server 1401 for storage and analysis.

### Demand Charge

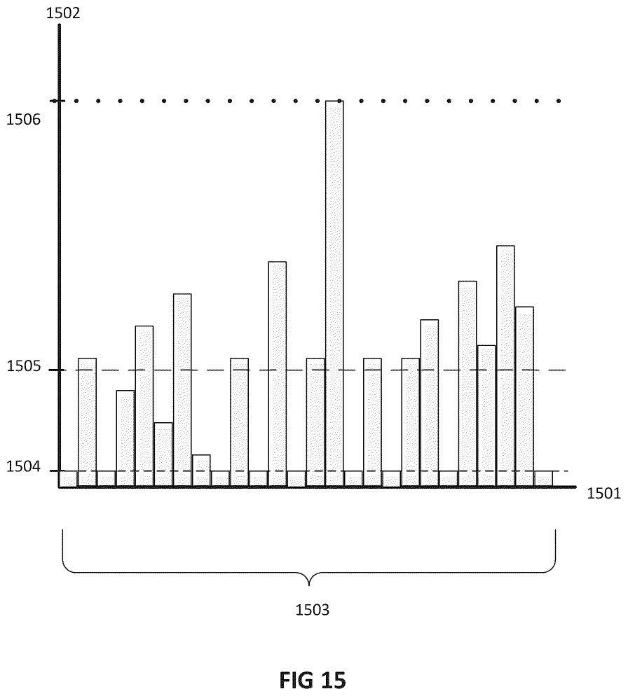

### FIG. 15

FIG. 15 shows the utility billing rates for a business customer. This example could be for a single charging station or an aggregate or charging stations.

The x-axis 1501 shows the time while the y-axis 1502 shows the consumed power (in kW). The power consumption varies over the billing period from the baseline 1504 to the peak demand 1506. The average power consumption 1505 can be determined over the billing period 1503.

Wireless Power Transfer electricity charges from the utility are expected to consist of both volumetric and demand components.

The volumetric component consists of fixed and variable charges: a transmission and distribution charge (T&D) for infrastructure; and a supply charge based on consumption during a billing interval. Note that the supply charge may be variable on time-of-day and seasonally (known as Time-of-Use (TOU)). The volumetric component is typically measured in kilowatt hours (kWh).

The demand component is based on the maximum amount of power required over a time period (e.g., single hour or set fraction of an hour) in a billing interval. The demand component is typically measured in kilowatts (KW).

Use of charger scheduling, which is coordinated the scheduling for charging of individual fleet vehicles to limit concurrent charging as well as efficient geospatial distribution of chargers can be used to reduce the demand charge component by an EV fleet.

Strategic placement of charger stations can be used to minimize infrastructure costs including T&D by limiting the number of chargers to less than one per every stop (on average). With this charger placement, multiple chargers may be installed at a stop served by more than one EV.

Preferential charging, Controlling SoC using wireless opportunity charging, during stops can, during the EV day, can be used to minimize electrical costs by charging only to reach the next charger (with reserve) during times of highest cost. Preferential charging can also include charging more (increasing the EV SoC) at stations with better electrical rates.

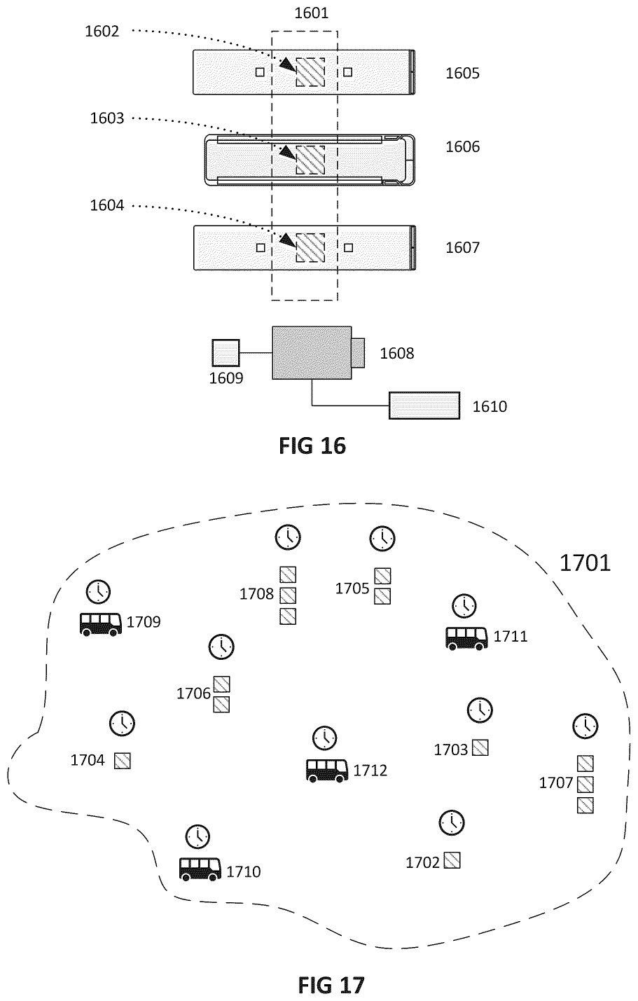

### FIG. 16

FIG. 16 shows an overhead view of a charging station at a stop, in this example a transit bus stop. The wireless power charging station 1601 in this example has three chargers 1602, 1603, and 1604 arranged to serve up to three electric vehicles concurrently. In this example, each charger 1602, 1603, and 1604 is serving a transit bus 1605, 1606, and 1607.

All three chargers are served via underground electrical connections (not shown) to power electronics 1608. The power electronics 1608 are connected to the utility grid via drop 1609. The utility may supply AC, DC, or AC three phase power via the drop 1609.

The Power electronics 1608 may include local power storage 1610 (e.g., a storage battery) which can be used to prevent excursions over the concurrent demand threshold.

The local energy storage unit 1610 (see U.S. Pat. No. 11,689,061, “CONTACTLESS SWAPPABLE BATTERY SYSTEM” for a working example of one such battery system) to allow “peak shaving” where energy is stored (trickle charged) during low electrical cost times and used during times of peak electrical cost. The battery storage may be physically swappable (for occasional or emergency use) or charged from the utility drop 1609 preferably during periods of low electricity cost. Alternative power sources such as wind or solar farms may be used to charge the local energy storage unit 1610.

To lower the demand and thus not exceed the desired maximum demand threshold the charging site controller may:
a. Allow each EV an equal share of available power.
b. Prioritize power to the EV with the greatest need (SoC needed to reach next charger)
c. Prioritize on arrival time and departure times so that power delivery changes as each vehicle arrives and departs
d. Prioritize power optimize energy based on time-of-day billing rates

Demand charges may be site specific (the size of the wire to a transformer and then meter), versus regional. Other avenues provide regional level controls (e.g., openADR—automated demand response).

Demand charges may be aggregated over a service area served by the utility for a single customer.

Additionally, the power available might be set by local or national governmental actions rather than a desired concurrent demand threshold to minimize utility demand charges.

### FIG. 17

FIG. 17 shows geographically, the ability to use strategic opportunity charging to lower (or at least manage) the utility demand charge portion of the power cost. In the region 1701, chargers are distributed to serve a fleet of EVs on routes (routes may be fixed (pre-planned) or ad hoc (revisable)).

The region includes single-charger stations 1702, 1703, and 1704, two charger stations 1705 and 1706 and three charger stations 1707 and 1708. These stations 1702, 1703, 1704, 1705, 1706, 1707, and 1708 and the number of chargers per station are sited based on projected need for charging of the fleet. Geographically, the stations 1702, 1703, 1704, 1705, 1706, 1707, and 1708 will be of varying distances from each other as are the passenger or delivery stops (not shown).

By coordinating the schedule for charging sessions of each fleet vehicle 1709, 1710, 1711, and 1712, the total demand for power can be kept below a threshold that would incur greater utility charges. This geospatial approach to total concurrent demand minimization can be optimized for the fleet further with the addition of additional, well-sited, opportunity charging stations to minimize the changing needs of EVs at any particular charging site or station.

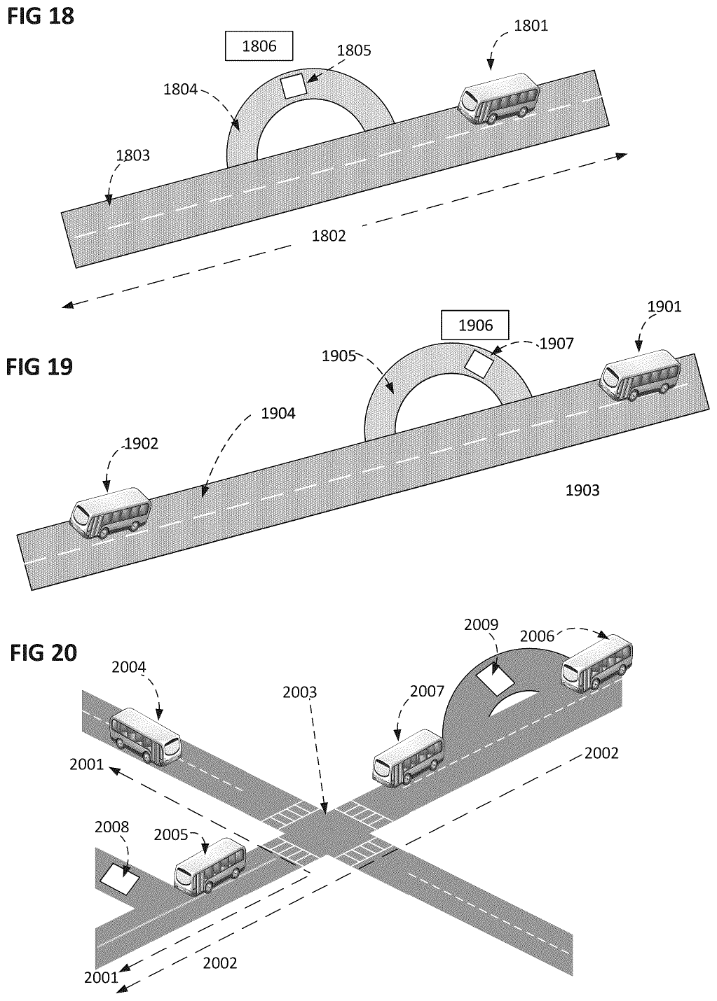

### FIG. 18

In FIG. 18, the case of a single electric bus (at a time) serving a single route is shown. The EV bus 1801 is traveling the route 1802 mapped to the local road 1803. An access road 1804 equipped with a wireless opportunity charger 1805 allows the EV bus 1801 to charge for set power level and up to the duration of the scheduled bus stop.

Information about the bus's 1801 status, traveling conditions, loading, adherence to schedule, and power consumption may be collected and transmitted in near-real time along the route 1802 or at the stop 1806.

### FIG. 19

In FIG. 19, the case of a multiple electric buses concurrently serving a single route is shown. This arrangement is made to decrease passenger wait times and/or to provide sufficient capacity to serve the route.

The first EV bus 1901 and the second EV bus 1902 are traveling the route 1903 mapped to the local road 1904. An access road 1905 for the bus stop 1906 is equipped with a wireless opportunity charger 1907 allows the first and second EV buses 1901 and 1902 to charge for set power level and up to the duration of the scheduled bus stop while passengers board or disembark.

Information about the buses 1901 and 1902 states, traveling conditions, loading, adherence to schedule, and power consumption may be collected and transmitted in near-real time along the route 1903 or at the stop 1906.

### FIG. 20

In FIG. 20, the case of a multiple electric buses concurrently serving multiple routes is shown. The buses may be from the same fleet or from different ones. In this example, the wireless charging infrastructure is shared.

A first route 2001 and a second route 2002 share the same local road network 2003. The first route 2001 is served by a first 2004 and second 2005 EV bus which move along the route 2001 in adherence to a first schedule. The second route 2002 is served by a first 2006 and second 2007 EV bus which move along the second route 2002 in adherence to a second schedule.

Placed along the first 2001 and second route 2002 is a wireless opportunity charger 2008. The first and second schedules must be aligned to permit each EV bus 2004, 2005, 2006, and 2007 sufficient charging time. The power consumption and this power supplied via the wireless opportunity charger 2008 (and other shared or unshared chargers such as wireless opportunity charger 2009) must also be coordinated (by the dispatch server 1001) to avoid exorbitant time-of-use electrical rates and utility demand charges as well as to not over-stress the wireless charger's ability to cool during and between charging sessions.

Information about the status of buses 2004, 2005, 2006, and 2007, traveling conditions, loading, adherence to schedule, and power consumption may be collected and transmitted in near-real time along the routes 2001 and 2002 or at the stop wireless charger(s) 2008 and 2009. Information about the wireless chargers 2008 and 2009 themselves may also be transmitted in near-real time or collected and transmitted periodically or triggered by an event (e.g., before, after, and during a charging session).

### ADDITIONAL EMBODIMENTS

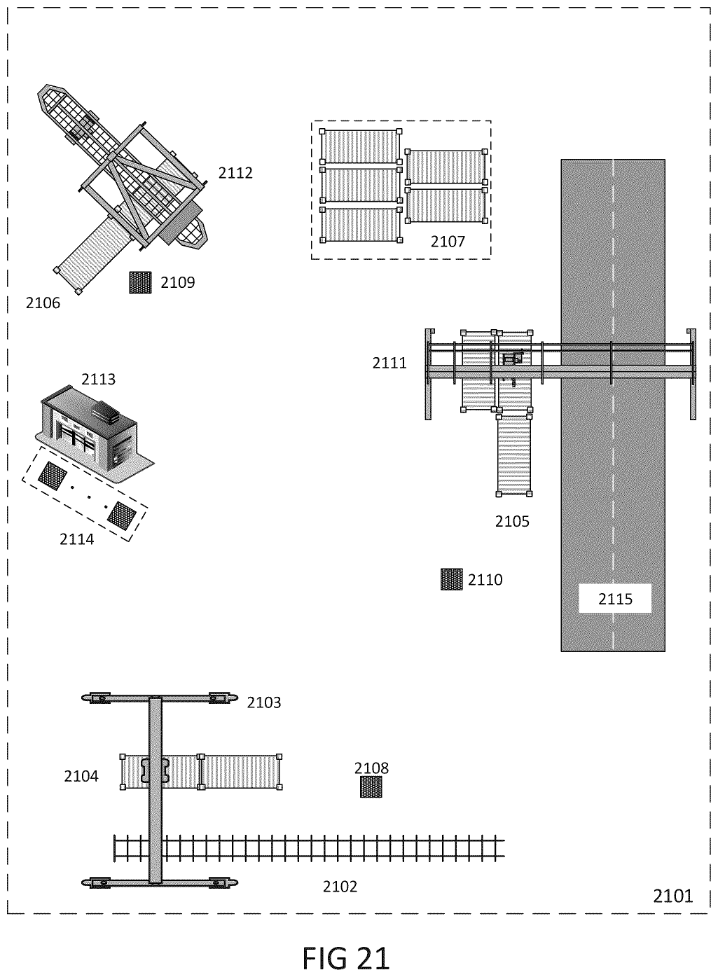

### FIG. 21

FIG. 21 is a diagram depicting an example drayage yard 2101 using electric cargo transfer vehicles (not shown) with strategic wireless opportunity charging. In this example, both the load weight and the distance traveled are the major determiners of battery consumption of the electric transfer vehicles (e.g., forklifts, side loaders, reach trucks). In FIG. 12, the movement of containerized cargo is described as an illustrative example.

Containers may be loaded and unloaded from a cargo rail system 2102 by yard vehicles. Specialized container handling machines 2103 are used to transfer cargo containers from visiting rail cars to a local rail yard stack 2104. The local rail yard stack 2104 is attended by transfer vehicles equipped with WPT receivers which may move containers to or from the truck yard stack 2105, the dockyard stack 2106 or to the temporary storage stack 2107. Since each stack; 2104, 2105, 2106, and 2107 are frequently visited by transfer vehicles, wireless chargers may be placed at each based on usage levels and wait time for containers. In this example, a rail yard charger 2108, a dockyard charger 2109, and a truck yard charger 2110 are installed. In this example, the storage stack 2107 is not equipped with co-located charger(s).

The truck yard stack 2105 may be added to by unloading trucks using the crane apparatus 2111, added to by transferred containers or reduced by loading of containers onto trucks or by rerouted containers to other transport or storage 2107 using transfer vehicles.

The dockyard stack 2106 may be added to by unloading trucks using the cargo crane 2112, added to by transferred containers or reduced by loading of containers onto ships or barges (not shown) or by rerouted containers to other transport or storage 2107 using transfer vehicles.

The storage stack 2107 can be added to or reduced by transfer of containers to and from each transport yard stack 2104, 2105, and 2106.

The transfer management application (similar to the software and databases used in the dispatch server 1001) uses near real-time data on cargo container weights (either manifest weight or weight via sensors onboard the transfer vehicles), cargo container location, transfer vehicle location, transfer vehicle state of charge, container destination (and thus distance to travel) and current queuing at the source and destination stacks to manage opportunity charging schedules for each charger 2108, 2109, and 2110 as well as charge levels, and charging duration for each charging session to minimize downtime and cost of travel.

The drayage yard 2101 also contains a rest and repair depot 2113 with its own associated wireless chargers 2114.

A highway 2115 spur serves the drayage yard 2101, here serving both as access for cargo truck access and for employee personal vehicles.

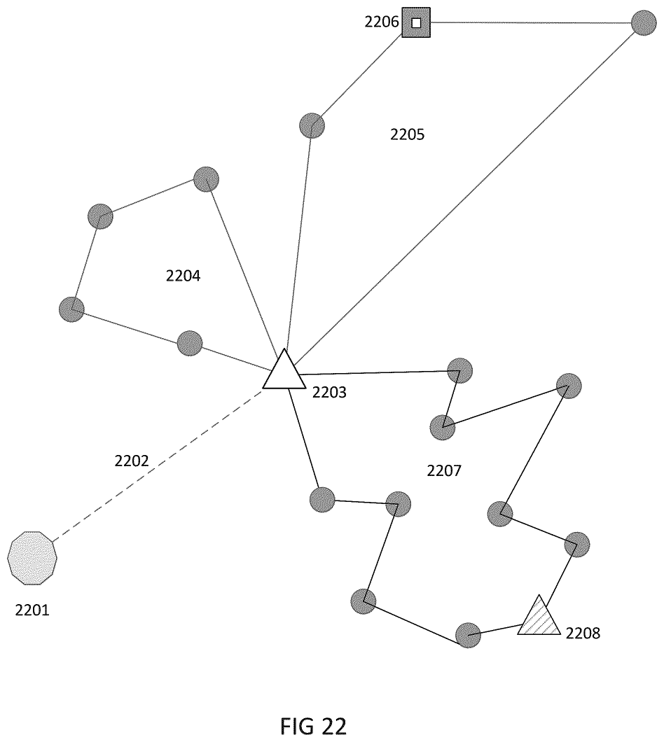

### FIG. 22

FIG. 22 geographically depicts an electric delivery vehicle route using strategic opportunity to minimize cost of travel.

Delivery vehicles are stored and maintained at the depot 2201 which may be separated by a distance 2202 from the first distribution center 2203. A wireless opportunity charger may be installed at the first distribution center 2203. The delivery vehicle has a first route 2204 with multiple stops. Stops may be delivery only, pickup delivery, or both depending on the type of delivery service offered. The first route 2204 returns the vehicle to the first distribution center 2203 where package loading or unloading can occur during an opportunity charging session if needed.

A second delivery route 2205 includes a third-party public or subscribed wireless charger 2206 where charging can be accomplished if necessary or desired to keep the delivery vehicle's battery in the desired SoC range.

At the end of the second delivery route 2205, the vehicle returns to the first distribution center 2203 where package loading or unloading can occur during an opportunity charging session if needed.

A third delivery route 2207 includes a visit to a second distribution center 2208 among the regular stops. The second distribution center 2208 may include a wireless opportunity charger which can be used to recharge the delivery vehicle. The third delivery route 2207 concludes at the first distribution center 2203 where the vehicle is unloaded and recharged to a charge level optimal for overnight storage at the depot 2201, taking into account the charge used to travel the distance 2202 to the depot 2201.

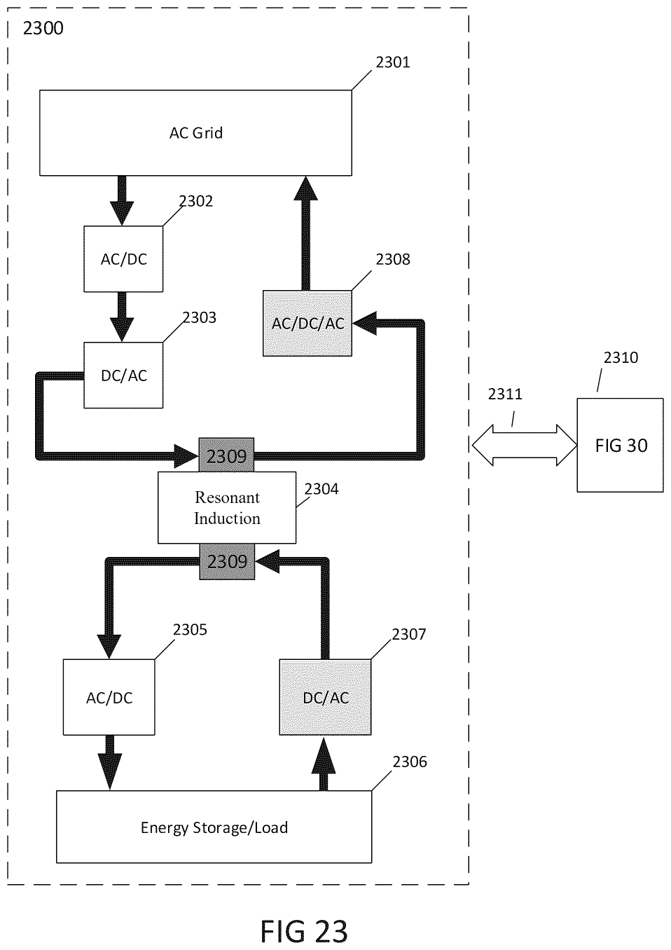

### FIG. 23

As described above, the factors for determining EV range 107, 108, 109 can include vehicle characteristics, battery pack characteristics, environmental factors, load carried, terrain traversed, and driver abilities. Even with a well-modeled system, excess electrical charge will be retained by the battery pack as a range buffer and as a battery lifespan preservative. In some cases, using managed Charging-as-a-Service (CaaS) with a need-weighted, geographically distributed WPT opportunity charging system, surplus energy (above the excess energy level) can be accumulated at low cost, stored, and discharged back to the utility grid to lower total electrical costs using electricity arbitrage. The CaaS system has access to not only the EV-related data and charging schedules generated by the route model, but also information about the charger sites under management including near real-time environmental and use data.

FIG. 23 is an exemplary high-level functional diagram for power flow through and conversion by a bidirectional wireless power transfer (WPT) system 2300 that may be used for electrical arbitrage in a sample configuration. The bi-directional capability allows selective wireless charging or discharging of EV battery packs as directed under the CaaS management.

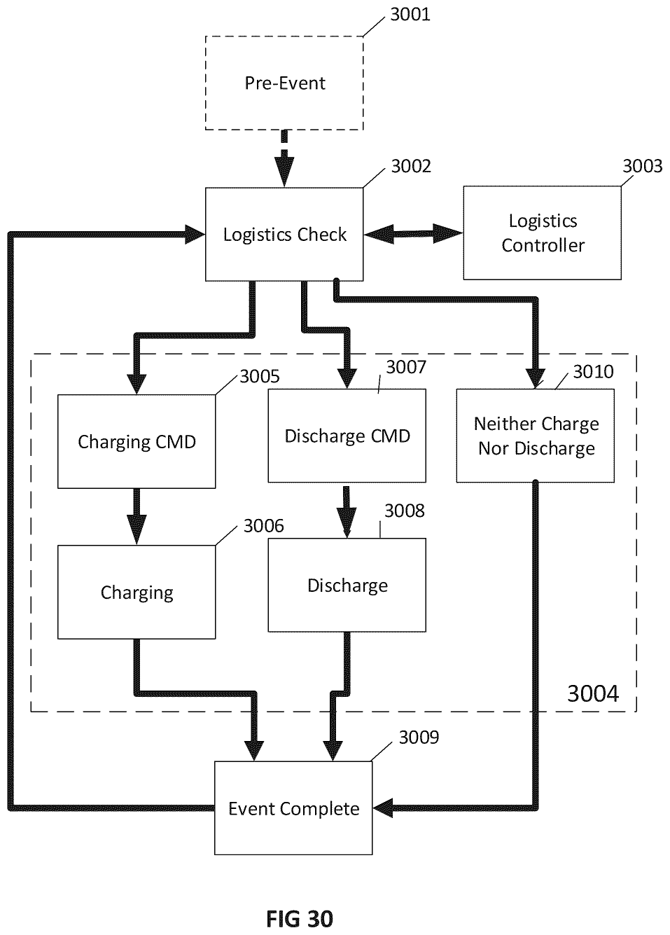

While certain components are by nature bi-directional and symmetric in operation (e.g., the resonant induction circuit also known as an open core transformer) and can be shared, the forward (charging) and reverse (discharging) power transmission paths will depend on divergent simplex architectures, requiring switches 2309, control logic 2310 (see FIG. 30 below), and communications link 2311 to activate and complete the power transmission paths for each of the forward (charging) and reverse (discharging) use scenarios. Presented here as both the forward and reverse paths, a WPT can be implemented (and optimized for) using only one (nominally the forward) path.

In the forward direction, power is nominally delivered from the utility grid 2301. Dependent on the grid connection, the power may be single phase alternating current (AC), direct current (DC), or multi-phase alternating current. The utility grid 2301 includes any transformers needed to step down voltages from high voltage transmission lines. In this example, single phase AC is delivered by the utility grid 2301, where a sufficient capacitance exists so that the power factor is adjusted to approximately 1 (unity).

The AC power may be converted to DC by the AC/DC converter 2302. This function can be achieved by an active (switch-based) or passive (diode-based) rectifier. The DC/AC converter 2303 takes the input DC power and converts it to a high frequency AC (nominally 85 kHz in this example) sinusoidal signal. The DC/AC conversion operation by the DC/AC converter 2303 can be accomplished using an inverter.

The AC power signal may be passed to the coupling, a resonant induction air core transformer 2304, with its primary and secondary coils. The AC power is converted to magnetic flux in the primary which is inductively coupled with the secondary. The secondary coil converts the received magnetic flux into an AC power signal. The AC power signal is passed to an AC/DC converter 2305. The AC/DC conversion function can be achieved by an active (switch-based) or passive (diode-based) rectifier.

The resultant DC signal is used to charge the energy storage device 2306, nominally a rechargeable chemical battery, but also could be a one or more of a capacitor bank, reversable fuel cell, solid state battery or a hybrid combination of the aforementioned. The DC signal can also be used to power an electrical device directly. Being bidirectional, the energy storage device 2306 can output stored power as direct current to the reverse transmission path. The DC power is converted by the DC/AC inverter 2307 to the necessary AC power signal.

This AC power signal is input into the resonant induction air core transformer 2304. In this reverse path scenario, the coils are reversed in operation from the forward path. The AC power is converted to magnetic flux in the primary coil of the resonant induction air core transformer 2304 which is inductively coupled with the secondary coil. The secondary coil converts the received magnetic flux into an AC power signal. The resultant AC power is adjusted in frequency by the AC/AC converter 2308. In one configuration, an AC/DC/AC converter is used as the AC/AC converter 2308, where the AC/AC frequency adjustment operation is accomplished using an AC/DC rectifier and then converted from DC to AC at the required frequency by an inverter circuit. The utility grid 2301 in this example includes the necessary transformers to translate the AC power to the desired voltage and AC/DC conversion, if necessary, for interfacing with utility supplied power.

In an alternative configuration, the case where a DC utility feed is available from the DC utility grid (not shown), the DC/AC converter 2303 can be sized to accept a DC feed directly, omitting need for the prior AC/DC stage 2302.

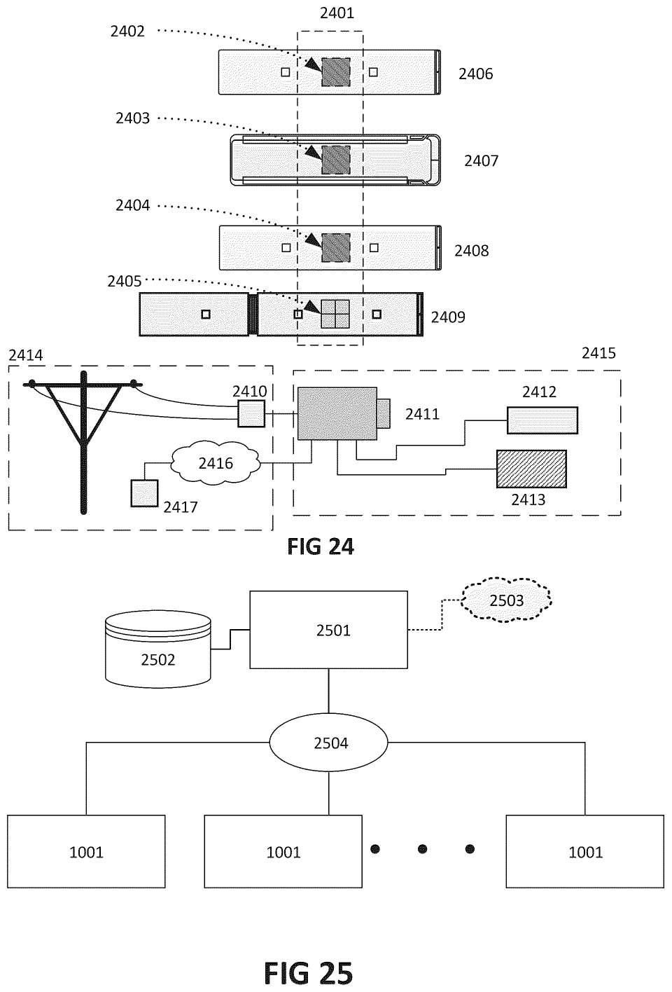

### FIG. 24

FIG. 24 is a diagram depicting a simplified example configuration for enabling electrical arbitrage using reverse metering at a WPT charging station in a sample configuration. To enable electrical arbitrage, both the EVs and wireless power charging stations installed in the ground are equipped for bidirectional charging.

FIG. 24 shows an overhead view of a charging station at, in this example, a transit charging station for EVs. The wireless power charging station 2401 in this example has four bidirectional chargers 2402, 2403, 2404, and 2405 arranged to serve up to four electric vehicles concurrently. In this example, each charger 2402, 2403, 2404, and 2405 serves an electrically powered bus 2406, 2407, 2408, and 2409, respectively. Note that in some installations, some or all chargers may be unidirectional only.

All four chargers 2402, 2403, 2404, and 2405 are served via underground electrical connections (not shown) to power electronics 2411 of a local microgrid 2415. The power electronics 2411 are connected to the utility grid 2414 via drop 2410. The utility grid 2414 may supply AC, DC, or AC three phase power via the drop 2410. In this example configuration, the power electronics 2411 are equipped with the necessary electronics to support both electric charging from the utility grid 2414 and discharging to the utility grid 2414. The utility drop 2410 has any needed transformers and electric metering to account for power transfer in either direction. Electricity can be harvested from visiting EVs or from the local power storage 2412 of the local microgrid 2415 when the dispatch server 1001 determined surplus electricity or surplus electricity is determined from the dispatch office 1001 of a CaaS management system 2501 (FIG. 25).

The local microgrid 2415 may include an ancillary local power storage 2412 (e.g., a storage battery) which can be used to prevent excursions over the concurrent demand threshold. The local power storage 2412 may also accumulate power from the visiting EVs 2406, 2407, 2408, and 2409 via the bidirectional chargers 2402, 2403, 2404, and 2405 when an EV has been identified (by the dispatch server 1001) as having surplus electricity stored.

In some remote installations, local power generation 2413 (e.g., diesel generator, solar, wind, hydroelectric, nuclear reactor (decay, fission, or fusion)) of the local microgrid 2415 may be used to supplement or replace the connections to the utility grid 2414.

In addition, a utility communications network 2416 may be provided that allows near real-time signaling to the controls of the local microgrid 2415 (shown in FIG. 24 as part of the power electronics 2411). This signaling can include current electrical prices and needs.

The utility discharge controller 2417 allows for coordination of charging and discharging from the local microgrid 2415, which may include eligible EVs, the local battery store 2412, and local power generation 2413. The utility discharge controller 2417 can signal the need for power inputs into the grid 2414 via the utility drop 2410.

### FIG. 25

In a fleet of commonly owned electric vehicles (EV) or for vehicles sharing in a Charging-as-a-Service (CaaS) program, the ability to manage electrical usage and storage over time allows for electrical arbitrage. Electrical storage includes local storage (e.g., battery, compressed air) at charger stations, excess state-of-charge (SoC) within each EV visiting a charging station, and battery-packs of parked EVs at a depot or yard.

Wireless Power Transfer chargers can be made bidirectional with the addition of parallel charging and discharging circuitry on the EV and ground-side as the inductive coupling between vehicle-borne and ground-side coils can function in either direction. The WPT charging and discharging (bidirectional WPT) can be controlled remotely for any EV or fleet under CaaS management and requires no driver or passenger interactions. The CaaS system or its subtending dispatch offices include location, use and scheduling data for both unidirectional and bidirectional charger capability. The EVs may be human driven, have driver assistance (partially autonomous) or be fully autonomous. The CaaS system and WPT system allows for automatic handling of charging, discharging, and adjustment of electrical storage based on extensive modeling and analysis of the route model.

Route modeling based on historical vehicle and route data is nominally performed at the dispatch server 1001 in the dispatch office, which has access to charger data, vehicle data, access to third-party data feeds (e.g., traffic, weather, electrical availability, electrical rates), geographic and topographic data for computations of modeled routes and route segments. The dispatch server 1001 also maintains (and updates) charger configurations, availability, scheduling charging sessions, and power availability and consumption. Both route modeling and charge management algorithms used in the dispatch server 1001 use trained machine learning to generate the predictive models for the CaaS.

One example of such electrical arbitrage can be seen in FIG. 6 where the two regional utilities have different electrical pricing (e.g., based on generation method(s) and capacities). In an example scenario, the charging station 603 served by utility grid 601 may charge EVs to greater than is forecast by the route model (using a second set of battery SoC threshold(s) for the surplus charge). When a surplus charged EV arrives at charging station 604 (which is served by utility grid 602), the surplus electricity can be transferred via the WPT system into local storage 2412 (for use by other EVs using or scheduled to use station 604) or to the local electrical grid 602 leaving the EV with a SoC within a first set of battery SoC threshold(s).

Another example of electrical arbitrage can be seen in FIG. 17 whereby scheduling surplus charging across a managed fleet of EVs 1709, 1710, 1711, and 1712 (or multiple managed fleets) can be used to extract, locally store, and deliver electricity to manage electrical cost over the service day. By selling power during peak usage times, electrical arbitrage can further decrease electrical cost to the managed fleet of EVs. The modeled power consumption and third-party data (e.g., electrical rates) allows for calculation of the surplus at each charging station 1702, 1703, 1704, 1705, 1706, 1707, and 1708. In some cases, the EV surplus electricity may be transferred to local electrical storage 2412 for future use by fleet EVs or for future timed selling opportunities in the event that the local storage is calculated to have its own excess power surplus.

Another example of electrical arbitrage can be seen in FIG. 21. In this example, un-used, under-used, or stored vehicles at the depot 2101 can be used (within SoC thresholds) as a local battery storage facility during the service day. Using the depot WPT bidirectional chargers 2108, 2110, and 2114, surplus power may be accumulated from the utility grid (not shown) from the EVs at times of low cost and then delivered back at periods of high demand for a profit.

FIG. 25 is a diagram of a system for managing a CaaS system at the functional element level in a sample configuration. In this example implementation, the CaaS management system 2501 is a processing platform including a processor that executes the functions described herein and interacts with local data storage 2502 and optional remote data storage 2503. One example of optional remote data storage 2503 could be a decentralized distributed database storing cached traffic, weather, public charger status and recent charging sessions, and the like. A data communication network 2504 connects the CaaS Management System 2501 to one or more dispatch offices including dispatch servers 1001. In this configuration, the dispatch servers 1001 provide the CaaS system with vehicle data, route data, electrical rate data, charger use, charger capability, charger location, and third party data for use in computing arbitrage values on one or more processors of the CaaS system.

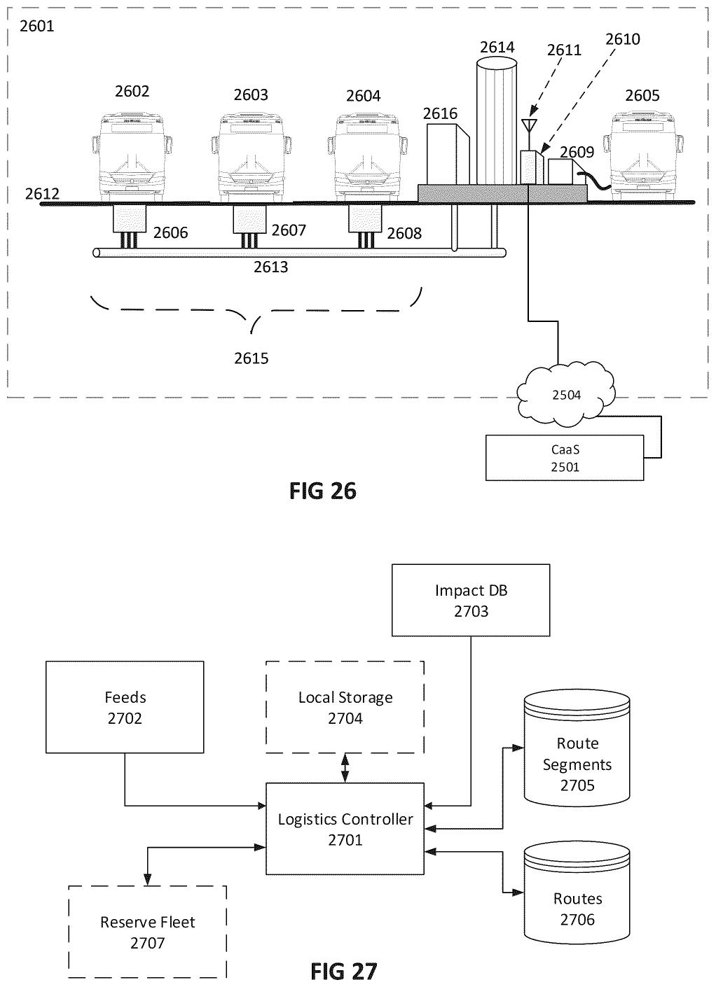

### FIG. 26

FIG. 26 is a diagram illustrating a hybrid depot for charging and discharging of parked fleet vehicles 2602, 2603, 2604, and 2605 in a sample configuration. The hybrid depot 2601 uses bidirectional wireless power transfer pads 2606, 2607, 2608 and wired power transfer 2609 under control of local power electronics 2610. The local power electronics 2610 interconnects the WPT 2615 and wired 2609 subsystems to the utility grid (not shown) and transforms and meters the electrical power in and out of the depot 2601 under the control of the CaaS management system 2501 via the local controller 2610. In this example, the CaaS management system 2501 is located remotely and connected to the local controller 2610 via a data network 2504. The local controller 2610 may also use a wireless (radio) network via the optional antenna 2611.

In the present depot example, the pavement 2612 supports the EVs and conceals the conduit 2613 for power, cooling, and communications between each WPT pad 2606, 2607, and 2608 and the power electronics 2610, thermal management 2614, and the local controller 2616. Alternatively, and not shown, overhead structural frames or gantries can be used to support the conduit 2613 as well as signage, directional signals, surveillance camera(s) (see U.S. Pat. No. 11,904,712; entitled “FOREIGN OBJECT DETECTION FOR WIRELESS POWER TRANSFER SYSTEMS”), and lighting.

### FIG. 27

FIG. 27 is a diagram of a CaaS system for enabling electrical power arbitrage including elements shown as functional entities that may be run on distinct or distributed processing hardware and data storage in a sample configuration. To enable electrical power arbitrage, a logistics controller 2701 tracks in near-real-time electrical pricing, surplus power on EVs, surplus capacity on EVs, and status of local power storage. The logistics controller 2701 uses the electrical cost and availability data in the arbitrage equation for maximization of profit. The logistics controller 2701 may coordinate with electrical utilities to supply electrical power based on the electrical demand, the electrical ramp-up, or based on price. The logistics controller 2701 may coordinate with electrical utilities to store electrical power based on the electrical supply or based on price.

The feeds 2702 include the spot prices for electricity associated with the geographic regions, the utility, or the services area. The information from the feeds 2702 may be overridden or supplanted by contractual terms with a utility or active coordination with a utility.

The impact database 2703 stores the impact of using the EV and local storage batteries 2704 for surplus storage with associated battery lifespan. Each EV and local storage may have a unique lifespan determinant model resulting in a unique total cost for surplus charging.

Wear of charging station components such as power electronics, cooling systems, and chargers is also maintained in the impact database 2703. In the case of modular chargers, data is kept for each coil assembly of each charger. In the case of hybrid wired/wireless charging stations 2601, data is maintained on power cords and connectors as well. The logistics controller 2701 uses the impact data in the arbitrage equation for maximization of profit.

The local storage 2704 is an optional component nominally co-located with individual charging. Nominally intended to supply the charger station and visiting EVs, the local storage 2704 may charge from or discharge to the utility grid or a charging EV at the direction of the logistics controller 2701. In the cases where EVs are used to store and transport surplus power, the local storage 2704 may accept and store power obtained from the EVs under direction of the logistics controller 2701.

Since each EV may have an estimated power level needed for each route segment and a reserve power level (set by an operator), additional surplus power capacity may be available (surplus is maximum allowed capacity minus the needed and reserve) for electrical storage and conveyance. The route segment database 2705 contains the estimated power and reserve power capacities for each route segment.

The routes database 2706 contains the summation of the route segments for each EV under management. Actions by the logistics controller 2701 affecting Total Cost of Distance (TCD) for each EV, each route segment, and each route as well as the power charged and discharged from each EV is stored in the routes database 2706.

Examples of actions performed by the logistics controller 2701 include charging above a nominal threshold, charging above a nominal current, and charging at higher or lower than nominal battery temperature. Other examples include discharging below the nominal threshold, discharging above a nominal current/rate, and discharging at higher or lower than nominal battery temperature.

The optional reserve fleet 2707 consists of EVs not presently in service that are connected by bidirectional chargers to a charging station. Acting much like the optional local storage 2704, the reserve fleet 2707 battery packs may be charged and discharged as needed to increase overall fleet electrical efficiency. The charging and discharging may involve the utility grid, or the local storage 2704. Charging levels can range from the lowest recommended state-of-charge (SoC) to the highest recommended state-of-charge (SoC) for each individual battery pack. Charging and discharging rates allowed also may be set to the nominal or recommended level for each individual battery pack. Some of the reserve fleet 2707 may be kept at an operational charge level, ready to be brought into service as needed, and thus would not be discharged below the set operational threshold level.

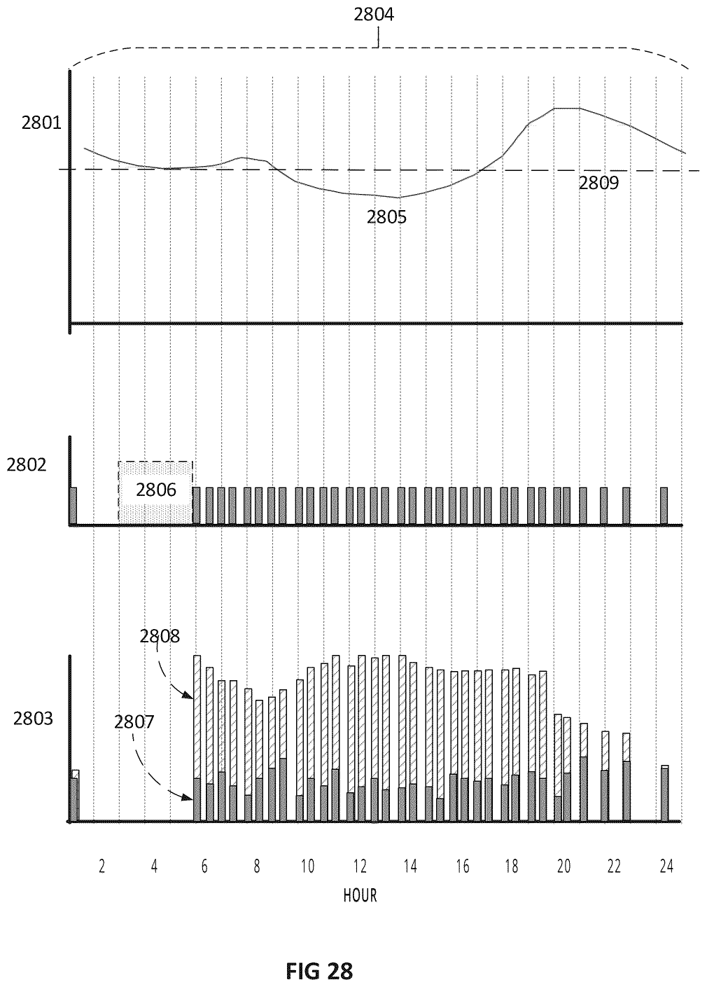

### FIG. 28

FIG. 28 includes graphs depicting the ability of an individual EV (e.g., a transit bus on a set route with a set schedule) to be used to store, convey, and discharge electrical power using a conservative charging strategy.

Graph 2801 shows the relative demand curve 2805 over an exemplary 24 hour timespan 2804.

Graph 2802 shows the time-series spacing of charging/discharging spots and travel for a transit bus over the exemplary 24 hour time-span 2804. Time spent off-line (in depot or otherwise parked) is denoted as a blocked timespan 2806.

Graph 2803 shows one example of electrical arbitrage using one electrical transit bus with the estimated power needed for travel shown 2807 and the surplus power 2808 at each stop on the route of scheduled stops during the exemplary time duration 2804. Since an EV may charge or discharge during a stop but can only discharge while on-route, the estimated power for travel 2807 is consumed on-route and may be replenished by reallocating the surplus or be re-charged at a stop.

By use of regenerative braking, an exception exists where an EV may recharge while on-route to above the operational level for the next route segment.

The charging strategy for the bus in this example is designed to maintain a maximum surplus charge by leaving the depot fully charged and then recharging only when the cost is below threshold 2809, using the surplus for operational needs when the cost is above threshold 2809.

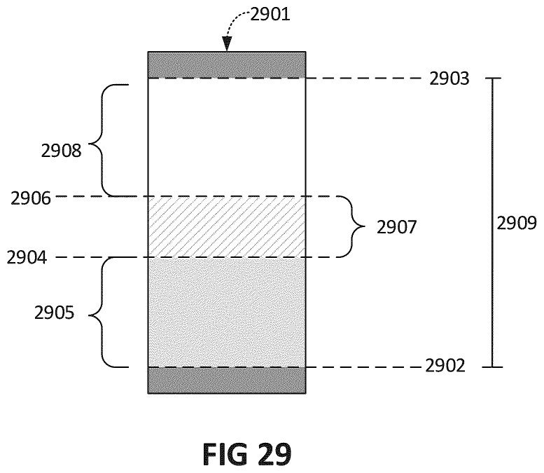

### FIG. 29

FIG. 29 depicts a battery pack 2901 with ranges and thresholds in a sample configuration. The battery pack 2901 is nominally comprised of a bank of battery cells with internal cross-connects and electronic circuitry to power an Electric Vehicle (EV). Dependent on battery chemistry (e.g., lithium-ion (Li-ion) battery (in its various configurations and chemistries)) or energy storage technology (chemical battery, reversible fuel cell, solid-state battery), the battery pack 2901 may have a lower 2902 charge threshold to minimize damage from discharge of the battery pack 2901. The battery pack 2901 also may have an upper charge threshold 2903 set minimize damage from the charging of the battery pack 2901. Between the upper 2903 and lower 2902 thresholds is the nominal charge range 2909. The upper 2903 and lower thresholds 2902 may be recommended by the battery pack manufacturer, set from experience gleaned from the EV's operational history, or determined by the operator.

For each route segment, the amount of charge above (at least) the minimum threshold 2902 is set as the operational level 2904. The operational charge 2905, above the minimum threshold 2902 and below operational level 2904 is thus the amount of charge needed to complete the route segment.

Due to potential vagaries in traveling the route segment, a reserve charge level 2906 is set (typically as a percentage added to the operational charge 2905). The difference between the reserve charge level 2906 and the operational charge level 2904 is the reserve charge 2907.

Above the reserve charge level 2906 and below the upper charge threshold 2903 is surplus battery capacity 2908. Charging of the surplus battery capacity 2908 can be used to decrease EV charging needs in subsequent route segments or can be used to store and transport electricity between charging stations to reallocate the charge.

### FIG. 30

The control logic for charging and discharging from battery packs is shown in FIG. 30. The control logic may be located at the bi-directional charger 2300, at the dispatch server 1001, and/or at the CaaS management system 2501. The pre-event 3001 may be any of number of triggering events that cause a logistics check 3002. The pre-event 3001 can be the arrival, alignment, and communications established when an EV arrives at a wireless charger. The pre-event 3001 can also be the plugging in of an EV(s) wired power connector, or the crossing of threshold charge at a local battery store (or member of the reserve fleet).

Alternately, a logistics check 3002 can be initiated by a logistics controller 3003. For example, a logistics check 3002 may be initiated upon detection of a utility pricing threshold being crossed, a contractual boundary being reached, the time-of-day, significant deviations from the power consumption of estimates, a change in route (e.g., new route segment), loss of power at a charging station or charger, reduction of charging capacity at a charging station, loss of communications with a charging station or charger, and the like.

The logistics check 3002 interrogates battery packs for status which is compared to baseline data. The status for an EV or local storage would include the current SoC, battery temperature, and charge/discharge capacity and capabilities.

Based on the logistics check 3002 and the fleet demand model, the logistics controller 3003 would signal the charger to do nothing or to charge or discharge the battery pack at 3004. The logistics controller 3003 may then set charging parameters for the EV with a charging command 3005 or set discharging parameters for the EV with a discharge command 3007. These commands 3005 and 3007 may override the parameters set in the EV's Battery Management System.

Once the charging 3006 or discharging 3008 is complete, the EV will be prepared to depart the charger or be sent a subsequent logistics check 3002 if needed and allowable by the EV schedule.

In the case that the EV is inactive, the inactive EV would re-allocate surplus power to operational and reserve power for the next route segment and is prepared to move out with Event Complete 3009.

If during a stop, the inert EV may receive a subsequent logistics check 3002, and the EV may then receive a charging command 3005 or a discharge command 3007 based on the new data. After charging 3006 or discharging 3008 is complete, the event is completed at 3009 and the EV is prepared to move off the charging pad (or unhook from the wired charger).

The logistics controller 3003 also may instruct the EV to neither charge nor discharge at 3010 before completing the event at 3009.

It will be appreciated that the control logic of FIG. 30 may apply for control of a single EV, a fleet of EVs, a reserve EV, and a reserve fleet of EVs with the understanding that a reserve EV typically will be managed to maintain its operational charge in case that EV is called into service.

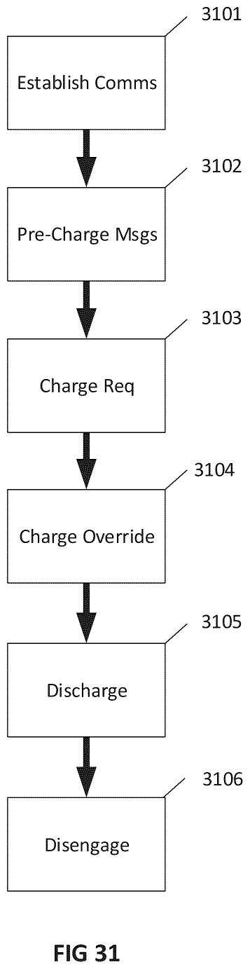

### FIG. 31

The operational flow for controlling the charging and discharging from an in-service EV (e.g., a transit bus on the set schedule on a set route with estimated operational charging levels and estimated power consumption per route segment) is shown in FIG. 31.

As illustrated in FIG. 31, the EV must first establish communications 3101 with the charger controller. For wireless or pantograph chargers, this may be via radio connection via the charging station infrastructure or by near-field communications with the wireless charger. For conventional wired systems, communications can be initiated upon physical connection of the plug-in connector.

Pre-charge messaging 3102 can include alignment and safety verification messaging.

The EV BMS attempts to start the charging session with a Charge Request message 3103.

The Charger Controller, acting on instructions from the logistics controller 3003 replies with a Charge Override 3104 message denying the charge request and instead providing the EV BMS with the parameters for the discharge.

The discharge 3105 of the EV battery system to the local storage or utility grid continues for the preset duration calculated to allow the EV to depart on schedule.

After the discharge 3105 completes, the EV disengages at 3106 and leaves the stop with at least the necessary charge (and reserve) to continue for the next route segment.

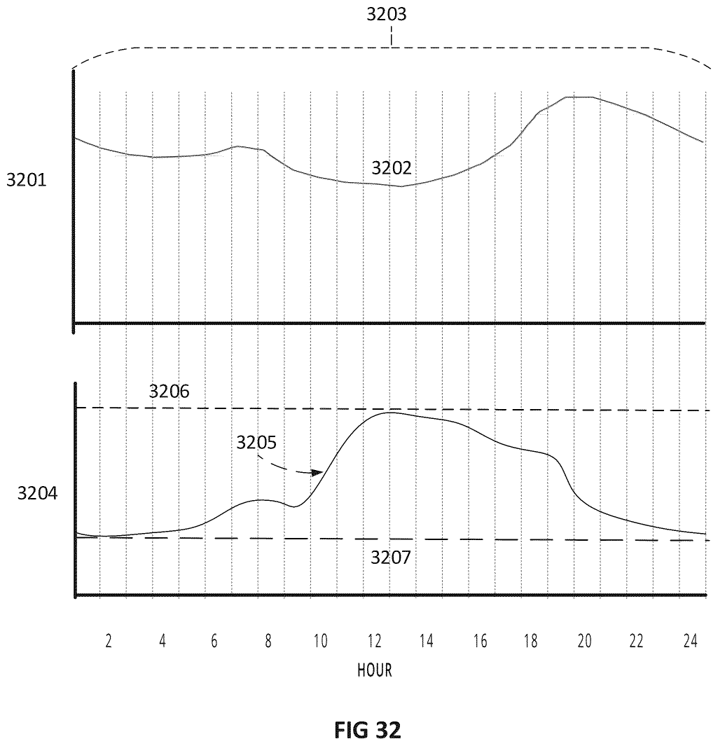

### FIG. 32

FIG. 32 includes graphs depicting the ability of an EV transit fleet (e.g., multiple buses serving set routes, each with a set schedule) to be used to store, convey, and discharge electrical power.

Graph 3201 shows the relative cost-of-power curve 3202 over an exemplary 24-hour timespan 3203 from the perspective of the local utility(s).

Graph 3204 graphically shows the surplus electrical power 3205 acquired, held, and returned to the utility grid (or local microgrids) by the transit fleet over the course of the exemplary 24-hour timespan 3203. The surplus electrical power can range between a maximum 3206 and the minimum 3207.

The transit buses in the fleet consume electricity traveling each route segment. Consumed electricity can be restored at any charging stop. Consumed electrical power can be restored by reallocating the surplus. The surplus can be added to at any charging stop where sufficient time and power are available. The surplus can be discharged at any stop with discharging capability and sufficient time. As described above, the timing of the charging/discharging is controlled based on a variety of factors including the electricity costs and the electricity demand curve for the fleet at different times of day (FIG. 28).

In addition, the charging/discharging from/to the utility grid may be coordinated with the local utility to minimize spikes in power resulting from unexpected charge/discharge from/to the utility grid. For example, the control logic of FIG. 30 may be adapted to send messages to the local utility grid on a periodic basis to provide a schedule of expected charge/discharge from/to the utility grid, thus enabling the utility grid to manage its charge allocation.

It will be further appreciated that EV operators (e.g., buses, delivery vans, taxis) often charge their fleets (some to all) overnight at the hub or depot where they park, unoccupied, and out-of-service during periods of low usage (e.g., night/early morning) or in-between operations (e.g., awaiting a pickup or delivery run). Depots may also offer ancillary services for the EVs such as cleaning and maintenance as well as access for human driver replacement.

With opportunity charging, an EV battery does not have to be sized to support the daily required range when fully charged. To minimize the battery size and investment in opportunity charging stations throughout the service area or service route, EVs often return to the depot with their batteries discharged (nominally above or at a longevity threshold). The depot charging can be factored into the total cost of distance in the nominal case where the EV leaves the depot at near full (below the safety threshold) battery capacity.

When using the opportunity charging scheme described herein whereby automatic conductive (e.g., pantograph, and/or wireless (e.g., inductive) chargers) are positioned geographically or along recurring routes, a depot stop may be considered a type of long duration opportunity charging stop. Note that the EV may, in the case of an inductive charger, be moved on and off the charging pad during the depot stop duration. Depot charging may be conductive (e.g., automated plug-in, pantograph, conductive rail) and/or wireless (e.g., inductive) depending on the operator's selection and capabilities of the fleet EVs.

With unmanned autonomous electric vehicles, the automatic nature of opportunity chargers (pantograph, inductive, robotic plug-in) is well-suited for both on-route and depot charging. Using opportunity chargers both on-route and at the depot allows for planned energy management at any point of the day to capture daily and seasonal variations in electricity prices and avoid utility demand charges from drawing too much electricity at once.

Using the dispatch center to manage the on-route and depot charging plan for fleet vehicles is preferable since SoC for each vehicle can be managed independently with knowledge of electrical needs for the upcoming service day. In an operative example, the dispatch office has knowledge of each fleet vehicle, on-route chargers and depot chargers. On-route chargers may include static or dynamic (e.g., electric road, dynamic wireless power transfer) chargers. From the EV SoC, route estimates, and schedule, a charging priority and reprioritization is determined for each scheduled EV at its arrival at the depot. In depot charging, scheduling controls the allocation of charging resources (both in charger time and in total power transferred). The goal of scheduling is to have each EV charged to an individual SoC goal before the start of the service period (e.g., the service day) with the minimal total cost in electricity, overhead costs, and below a duty cycle for the chargers (set to prolog the service life of the chargers).

In an exemplary scheduling scheme for depot charging, for each arriving EV the depot controller queries the dispatch server 1001 of the dispatch office (or has already downloaded the next service period's schedule routes) for departure time, desired SoC, and electrical rate structure for the EV chargers at the depot. The depot controller also queries the EV for current SoC and charging capabilities (including state of repair). Optionally the arriving EV's required SoC for the next service period can be inferred by the electric vehicle's history (from the last run, same route or the weighted average of same route), or the history of similar (make, model, manufacturer, age) electric vehicles who recently completed the same scheduled route.

If charging is required to meet the desired SoC for an arriving EV, then the depot controller, using a first-in-first-scheduled (FIFS) approach, selects a charger, charging start and charging duration for the EV. These charging allotments are selected to minimize electrical cost of charging for the depot while maximizing the probability of having each EV leave the station with the desired SoC. A scheduled EV is directed to the selected charger or standby position based on its charging start time. Since additional EVs arrive at the depot, the entire schedule may need to be recomputed for each arrival, modifying the charging start times for those EVs who are still in standby (i.e., not yet charged).

The FIFS schedule scheme, while functional, may not be an optimal scheduler for all depots. Other scheduling schemes may include delta, which works by weighting the schedule to charge the biggest/smallest SoC delta (difference between SoC target and actual SoC) as priority. The delta scheme could use predicted or historical SoC information for each arriving EV as well as scheduled depot arrival time to pre-populate the charging schedule. The delta prioritization scheme also may use cost of power to further weight the use of chargers to favor the lowest cost of power. Alternatively, the delta prioritization may spread available power over all charger/EV combinations when an arrived EV is not at its target SoC, while keeping instantaneous power use under a desired threshold (e.g., to minimize the utility demand charge).

As another alternative, dynamic optimization (e.g., a Bellman equation) may be used for ordering and assignment of the EV charging schedule. For example, Equation 1.1 below is a Bellman equation which is a mathematical view of a scheduler that uses a weighted reward to encourage charging efficiency.

$$min {V}_{π} ( s ) = {E}_{π} [ {R}_{t + 1} + γ * {V}_{π} ( {S}_{t + 1} ) \vert {S}_{t} = s ] where : \qquad EQN . 1.1$$

V_{π}(s) is the value of state s,
E_{π}[Rₜ₊₁] is the expected value of the immediate reward,
E_{π}[γ*V_{π}(Sₜ₊₁)] is the discounted value of the next state,
Sₜ=s is the value if the agent starts at state s,
   and where:

$${R}_{t + 1} = [ {Cost}_{demand} ( t + 1 ) + {Cost}_{tou} ( t + 1 ) + {Cost}_{battery \_ wear} ( t + 1 ) - {Profit}_{operations} ( t + 1 ) ]$$

and:
Cost_{demand} is the demand charge implications for a time step,
Costₜₒᵤ is the time of use (tou) charge for a time step,
Profitₒₚₑᵣₐₜᵢₒₙₛ is the value of operating buses (i.e., exit at target SoC),
Sₜ is the state at time t,
Rₜ(s) is the reward at time t given state s,
Vₓ(s) is the value of acting on policy π at state s,
E_{π}() is the expected value of the equation in parentheses, and
γ is the fractional discount of future value.

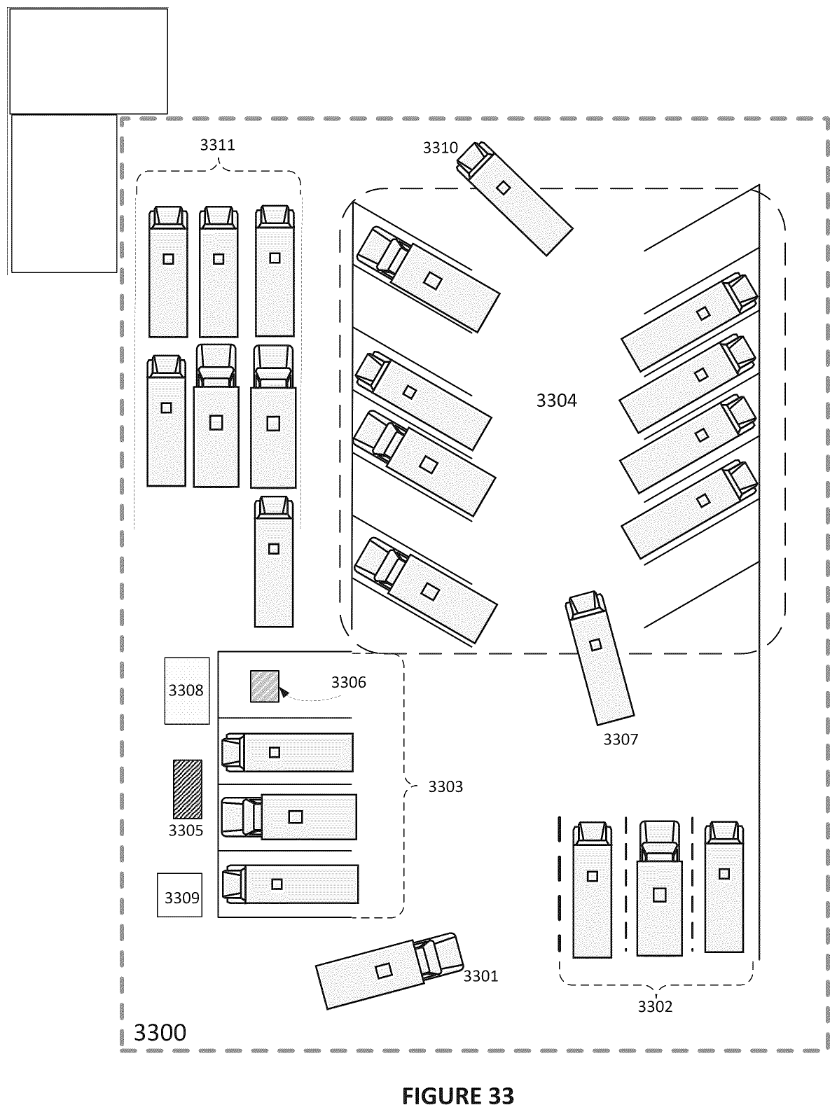

### FIG. 33

FIG. 33 illustrates an exemplary electric vehicle depot 3300. Such a depot can serve one or more varieties of nominally fleet EVs. In this example, the depot is arranged for human-driven vehicles but could serve autonomous vehicles or a mix of both types of vehicles.

When an arriving EV 3301 enters the depot, a queue 3302 may be used to hold the vehicle until a charger-equipped parking stall in the charging position 3303 (shown here as a group of inductive WPT chargers but could be equipped with wired or Pantagraph chargers) is available or a holding spot (selected from the standby pool 3304) is assigned. In FIG. 33, a common power distribution and thermal control system 3305 is shown. Charger 3306 has completed a charging session for the now charged EV 3307 and has not been reassigned. The now charged EV 3307 will move to a holding position either in the standby pool 3304 (if additional charging is required) or the outbound pool 3308. Note that the outbound pool 3308 can include EVs not assigned to service in the next service period (e.g., day). Such vehicles may be charged according the route schedule or to a nominal storage level (e.g., 40-50% SoC) for longer-term storage.

The charging positions 3303 are individually assignable based on the charger type and power level desired for charging. As a charged EV 3307 departs its assigned charger 3306 in accordance to the depot charger schedule, another EV from the queue 3302 or the standby pool 3304 may be assigned.

An EV 3309 leaves the chargers 3303 and the standby pool 3304 when charged and in accordance with the depot schedule. The charge level may be fully charged, charged to battery safety or longevity threshold, or the minimum power needed to reach at least one available charger on the scheduled route.

Local utility interconnection 3310 acts as both an interface to the power grid but also as the communications connection to utility data sources.

The Depot Controller 3311 shown as a separate, local physical entity provides power monitoring, wireless communications with the EVs present (and optionally those on approach), resource (power, charger, EV parking) monitoring and interconnection to the dispatch server 1001 (for instance, where the depot controller 3311 and the dispatch server 1001 are physically as well as functionally separate).

In addition to on-route charging used to lower the total cost of travel by managing the EV SoC and charging sessions, depot level charging sessions may also be similarly coordinated by the dispatch server 1001 or a local, depot level controller 3311 that communicates and coordinates with the dispatch server 1001.

Depot Peak Shaving is a cost minimization effort using both the necessary electricity cost and the utility charge demand threshold limitation during depot charging. Depot peak shaving also includes time-of-use (TOU) control, taking advantage of variable (e.g., long) charging rates to lower metered electrical cost to a local optimum considering the electrical charging needs of the served EVs.

Opportunity charging electrical cost containment, with the ability to control electrical costs by scheduling charging sessions at geographically distributed chargers, is reduced since the depot is a nominal fixed location that processes a number of EVs, although in one alternative model, drivers take their vehicle home off-shift while in another model, autonomous fleet vehicles may charge at geographically distributed chargers and then go to standby status in public or private parking.

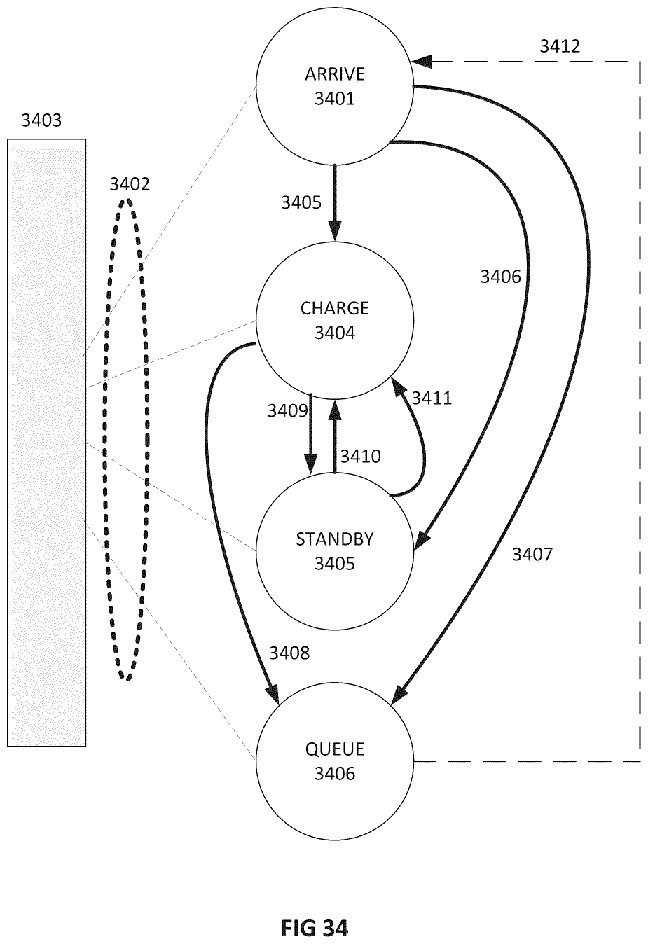

### FIG. 34

FIG. 34 is a state diagram of the operation of the exemplary electric vehicle depot of FIG. 33 in a sample configuration.

The depot charging operation starts with the EV arriving 3401 at the depot. Notification of arrival is reported over the radio data link 3402 to the scheduler 3403 function residing on the depot controller 3311. Arrival notification initiates the processing of EV specific data for consideration of scheduled time-of-arrival, current SoC, scheduled time of departure, and vehicle characteristics. Actual time-of-arrival is recorded for each EV arriving 3401.

Considered in the depot charging algorithm are parameters including: the EV charging duration (from schedule), power needed, first EV out (from schedule), and external (non-schedule) factors which include the cost of power, availability of power (under threshold(s), predictive factors to the EV schedule (e.g., weather), predictive factors to charging (ambient temperature), EV SoC (at any time after arrival), and the like.

Calculated from the EV, depot, and external factors, the scheduler 3403 produces three schedules (EV charging schedule, charger schedule, and aggregate power use schedule) that allow optimization of charging, and the setting of thresholds allows for simple metrics to inform customers of deviations from minimum cost charging. Historical information from each EV and charger allows for health checks based on deviations from last or predicted behaviors.

The scheduler 3403 determines where and when the arriving EV will be directed. The scheduler 3403 establishes a charging priority based on the schedule for each individual EV, the availability of chargers, and the availability of power on EV arrival which may perturb the queuing list and require recalculation.

After Arrival 3401, the EV may be directed to Charging 3404, Standby 3405, or Outbound Queue 3406 as assigned by the scheduler 3403. EVs directed at 3407 to undergo charging 3404 may charge until the desired SoC is reached, thereupon directed to transition 3408 to the Outbound Queue 3406. An EV may be returned 3412 from the Outbound Queue 3406 in limited cases (e.g., a route update for the EV that requires additional charging over the previously desired SoC, a mechanical or electrical issue that requires maintenance and then subsequent charging to recover to the desired SoC). When an EV is returned 3412 from the Outbound Queue 3406 it can be considered a newly arriving EV 3401.

EVs undergoing charging 3404 may charge until interrupted by a reprioritization event (e.g., newly arriving EV or charger outage, or power limitation) where the desired SoC is not reached. In this case, the partially charged EV will be directed to transition 3409 to the standby pool 3405.

An arriving EV may be directed to move 3410 to the standby pool 3405 to await future direction to move 3411 to charging 3404. Similarly, an EV that was partially charged previously can be returned 3413 to charging 3404.

If an Arriving EV SoC is sufficiently charged to meet the desired SoC to start the next service period, upon arriving 3401, such an EV will be directed to move 3414 to the outbound queue 3406.

Dependent on the owner/user's criteria (which includes the design of the facility), one of two broad classes of scheduling algorithms may be used: preemptive and non-preemptive. With a simple non-preemptive scheduling, an arriving EV is assigned a charger and power allocation based on its arrival time. The EV can queue before proceeding to an assigned or available charger. Once in a charging position, the EV can receive (variable) power until the SoC goal for that EV is met. Once charging is complete, the EV can proceed to off-line parking or depart the depot. Power variability is introduced as a way to compensate for multiple EVs charging concurrently while keeping power consumption under the demand threshold.

Alternately, still using non-preemptive scheduling, an arriving EV can be assigned a charging priority based on its departure time and/or total charging time needed. Once its priority is reached, the EV can proceed to an assigned charger and receive power until the SoC goal for that EV is met. Once charging is complete, the EV can proceed to off-line parking or depart the depot. Note that the total charging time needed can be based on the arriving EVs reported current SoC versus SoC goal or predicted SoC versus SoC goal. Using the predicted SoC allows for pre-arrival allocation of priority. By allocating available charger and power resources over time windows, power usage levels may be managed to minimize the cost of electrical power including not exceeding a utility-set demand threshold.

On the other hand, with preemptive scheduling, an arriving EV is assigned a charging priority based on its departure time and/or total charging time needed. This priority may be changed at any time due to power constraint (e.g., staying under a demand charge threshold) or by arrival of an EV with an earlier scheduled departure time. The change in priority may include interruption of an underway charging session and return of the partially charged (i.e., below the goal SoC) EV to a standby position. A new priority will be assigned to the arriving EV based on scheduled departure and recalculated charge level (or charger time) needed. Once the new priority is reached, the arriving EV can return to the charger for additional charging. Additional arriving EV's may bump the arriving EV from the charger again as reprioritization for the arrived EV fleet reoccurs.

Similarly, the arrival of an EV and assignment of a higher priority may result in reallocation of power with EV(s) currently being charged at lower rates than originally set to achieve individual SoC goals. The charging rate may be reset at any time and initiate a reprioritization event for all arrived EVs.

The inefficiencies and overhead of interrupting a charging session and moving an EV to-and-from the charging position to a standby parking positioning can be mitigated by having a charger at each standby parking position. However, even in that scenario, power allocation must be considered with the preemptive scheduling algorithm.

Selection of preemptive or non-preemptive scheduling includes judging of multiple factors including depot power allocation (total power available below the demand threshold), number of chargers, number of entry or standby positions at the depot, and availability of drivers (not applicable for autonomous EVs) for moving EVs between positions.

A hysteresis value may be determined for the charger availability and another for charging power allocation so as to increase the efficiency of charging over time by preventing delays when a higher priority EV displaces another in the schedule. For instance, the hysteresis value may prevent the immediate cessation of charging to EVs currently charging, but rather displace the next EV scheduled for charging if the remaining charging time is low, the remaining charging amount is low, or the EV-to-EV cutover time is greater than the time savings to schedule.

The scheduler 3403 may also be triggered for a charging schedule recalculation due to issues and errors in EV charging and unforeseen changes to the electric vehicle or the EV fleet routing. Errors that trigger schedule recalculation include: the vehicle is removed from charging prematurely (SoC not reached), charger or vehicle faults that prevent charging, and depot power outages. Unforeseen events include EV SoC and schedule updates due to weather changes and EV SoC and schedule updates due to weather forecast changes. Also included in unforeseen events is the addition of new EVs to the fleet or EV population served by the depot or a new route (or routes) is added to the fleet or EV population served by the depot and the arrival of a previously unserved EV from outside the served EV population.

The depot 3300 also may be equipped with bidirectional chargers.

While examples have been provided for commercial vehicles such as buses, drayage vehicles, and delivery vehicles, it will be appreciated that the methods described herein may also be applied to non-commercial vehicles such as EVs driven by individuals with or without software-based driving assistance. These same methods can be used for autonomously driven vehicles.

We claim:

1. A method for managing charging of Electric Vehicles (EVs) at a depot equipped with at least one EV charger, the method comprising:
for each EV arriving at the depot:
collecting data from the EV including a current state of charge (SoC), an SoC goal, a route estimate, and a charging schedule;
from the collected current SoC, SoC goal, route estimate, and charging schedule for the EV, determining a charging priority for the EV relative to other EVs at the depot; and
determining whether charging is required to meet the SoC goal of the EV and, if so, selecting a charger of the at least one charger for charging the EV and determining a charging start time and charging duration for the EV in accordance with the charging priority and the SoC goal of the EV, wherein determining the start time and charging duration comprises running an optimization algorithm that concurrently optimizes a minimal total cost of electricity for total power transferred to the EV during charging at the depot while maximizing a probability of the EV leaving the depot with its SoC goal satisfied.

2. The method of claim 1, wherein the collecting data includes a depot controller querying a dispatch server for or downloading schedule routes for a next service period of the EV and determining from the schedule routes a departure time for the EV, the SoC goal of the EV, and electrical rate structure for the at least one EV charger.

3. The method of claim 1, wherein the collecting data includes a depot controller querying the EV arriving at the depot for its current SoC and charging capabilities.

4. The method of claim 1, wherein the collecting data includes a depot controller inferring the current SoC of the arriving EV for a next service period from the EV's history on a route to the depot or from a history of a similar EV that has previously completed the route to the depot.

5. The method of claim 1, wherein selecting the charger for charging the EV comprises determining the charging start time for the EV and selecting a charger available at the charging start time.

6. The method of claim 5, wherein when the charger for charging the EV is unavailable, directing the EV to a standby position until the charging start time.

7. The method of claim 6, further comprising, upon arrival of another EV with a higher charging priority, recalculating at least the charging start time for the EV when the EV is in the standby position.

8. The method of claim 1, wherein the optimization algorithm implements electricity peak shaving to manage time of use of the at least one charger to take advantage of variable electricity rates at different times for charging to lower total electrical cost of the depot to a local optimum in accordance with electrical charging needs of EVs served by the depot.

9. The method of claim 1, wherein the optimization algorithm comprises a first-in-first-scheduled algorithm that schedules the EV for charging based on its time of arrival at the depot.

10. The method of claim 1, wherein the optimization algorithm comprises a delta algorithm that schedules the EV for charging based on a size of a delta between its SoC and the SoC goal.

11. The method of claim 10, wherein the delta algorithm uses predicted or historical data of the EV and a scheduled depot arrival time to pre-populate the charging schedule for the EV.

12. The method of claim 10, wherein the delta algorithm uses cost of power at each charger of the at least one charger to weight use of each charger to favor charging of the EV by an available charger of the at least one charger having a lowest cost of power.

13. The method of claim 10, wherein the delta algorithm controls the at least one charger to spread available power over all charger/EV combinations at the depot when the EV is not at its SoC goal while keeping instantaneous power use under a desired threshold to minimize a utility demand charge.

14. The method of claim 1, wherein the optimization algorithm orders and assigns the EV to a charger in accordance with a charging schedule determined by a dynamic optimization algorithm that uses a weighted reward to encourage charging efficiency in accordance with the following:
$$min {V}_{π} ( s ) = {E}_{π} [ {R}_{t + 1} + γ * {V}_{π} ( {S}_{t + 1} ) \vert {S}_{t} = s ]$$
where:
V_{π}(s) is a value of state s,
E_{π}[Rₜ₊₁] is an expected value of an immediate reward,
E_{π}[γ*V_{π}(Sₜ₊₁)] is a discounted value of a next state,
Sₜ=s is a value if an agent starts at state s,
and where:
$${R}_{t + 1} = [ {Cost}_{demand} ( t + 1 ) + {Cost}_{tou} ( t + 1 ) + {Cost}_{battery \_ wear} ( t + 1 ) - {Profit}_{operations} ( t + 1 ) ]$$
and:
Cost_{demand} is a demand charge implications for a time step,
Costₜₒᵤ is a time of use (tou) charge for a time step,
Profitₒₚₑᵣₐₜᵢₒₙₛ is a value of operating the EV,
Sₜ is a state at time t,
Rₜ(s) is a reward at time t given state s,
V_{π}(s) is a value of acting on policy π at state s,
E_{π}() is an expected value, and
γ is a fractional discount of future value.

15. The method of claim 1, wherein determining the start time and charging duration comprises producing a charging schedule for the EV, a schedule for the at least one charger, and an aggregate power use schedule for the depot.

16. The method of claim 1, wherein determining the charging priority for the EV is based on the schedule of the EV, availability of a charger of the at least one charger, and availability of power upon arrival of the EV at the depot.

17. The method of claim 1, wherein determining the charging priority for the EV is based on at least one of a departure time of the EV from the depot or a total charging time needed to charge the EV to the SoC goal.

18. The method of claim 1, wherein determining the charging priority for the EV comprises determining a hysteresis value for availability of a charger of the at least one charger and a charging power allocation to increase efficiency of charging over time by preventing delays when a higher priority EV displaces an EV currently being charged.

19. The method of claim 1, further comprising triggering a recalculation of the charging priority of the EV when the EV is removed from charging prematurely where the SoC goal has not been reached, the selected charger or EV faults to prevent the SoC goal from being reached, or the depot experiences a power outage during charging of the EV.

20. The method of claim 1, further comprising triggering a recalculation of the charging priority of the EV as a result of an SoC change of the EV or a schedule change of the EV as a result of a weather change or weather forecast change.

21. The method of claim 1, further comprising triggering a recalculation of the charging priority of the EV as a result of addition of a new EV or a previously unserved EV to a fleet of EVs serviced by the depot or a new route added for service by the fleet of EVs serviced by the depot.

22. The method of claim 1, wherein a charger of the at least one charger is bi-directional, further comprising determining that the EV has an SoC at or above its SoC goal and initiating transfer of energy from the EV to a utility grid for electrical arbitrage or local storage for later use at the depot. 23 A system that manages charging of Electric Vehicles (EVs) at a depot, comprising:
at least one charger;
a wireless communication system for communicating with EVs; and
a depot controller comprising a processor that executes instructions to perform operations comprising:
receiving from the wireless communication system an indication that an EV has arrived at the depot;
for each EV arriving at the depot:
collecting data from the EV including a current state of charge (SoC), an SoC goal, a route estimate, and a charging schedule;
from the collected current SoC, SoC goal, route estimate, and charging schedule for the EV, determining a charging priority for the EV relative to other EVs at the depot; and
determining whether charging is required to meet the SoC goal of the EV and, if so, selecting a charger of the at least one charger for charging the EV and determining a charging start time and charging duration for the EV in accordance with the charging priority and the SoC goal of the EV,
wherein the instructions executed by the processor implement an optimization algorithm that determines the start time and charging duration by concurrently optimizing a minimal total cost of electricity for total power transferred to the EV during charging at the depot while maximizing a probability of the EV leaving the depot with its SoC goal satisfied.

24. The system of claim 23, further comprising a dispatch server, wherein the depot controller queries the dispatch server for or downloads schedule routes for a next service period of the EV and determines from the schedule routes a departure time for the EV, the SoC goal of the EV, and electrical rate structure for the at least one EV charger.

25. The system of claim 23, wherein the depot controller queries the EV arriving at the depot via the wireless communication system for the current SoC and charging capabilities of the EV.

26. The system of claim 23, wherein the depot controller executes instructions to infer the current SoC of the arriving EV for a next service period from the EV's history on a route to the depot or from a history of a similar EV that has previously completed the route to the depot.

27. The system of claim 23, wherein the depot controller selects the charger for charging the EV by determining the charging start time for the EV and selecting a charger available at the charging start time.

28. The system of claim 27, wherein when the charger for charging the EV is unavailable, the depot controller directs the EV to a standby position until the charging start time.

29. The system of claim 28, wherein, upon arrival of another EV with a higher charging priority, the depot controller executes instructions to recalculate at least the charging start time for the EV when the EV is in the standby position.

30. The system of claim 23, wherein the optimization algorithm includes instructions, that when executed by the processor, implement electricity peak shaving to manage time of use of the at least one charger to take advantage of variable electricity rates at different times for charging to lower total electrical cost of the depot to a local optimum in accordance with electrical charging needs of EVs served by the depot.

31. The system of claim 23, wherein the optimization algorithm includes instructions, that when executed by the processor, implement a first-in-first-scheduled algorithm that schedules the EV for charging based on its time of arrival at the depot. 32 The system of claim 23, wherein the optimization algorithm includes instructions, that when executed by the processor, implement a delta algorithm that schedules the EV for charging based on a size of a delta between its SoC and the SoC goal.

33. The system of claim 32, wherein the delta algorithm includes instructions that, when executed by the processor, use predicted or historical data of the EV and a scheduled depot arrival time to pre-populate the charging schedule for the EV.

34. The system of claim 32, wherein the delta algorithm includes instructions that, when executed by the processor, use cost of power at each charger of the at least one charger to weight use of each charger to favor charging of the EV by an available charger of the at least one charger having a lowest cost of power.

35. The system of claim 32, wherein the delta algorithm includes instructions that, when executed by the processor, control the at least one charger to spread available power over all charger/EV combinations at the depot when the EV is not at its SoC goal while keeping instantaneous power use under a desired threshold to minimize a utility demand charge.

36. The system of claim 23, wherein the optimization algorithm includes instructions that, when executed by the processor, orders and assigns the EV to a charger in accordance with a charging schedule determined by a dynamic optimization algorithm that uses a weighted reward to encourage charging efficiency in accordance with the following:
$$min {V}_{π} ( s ) = {E}_{π} [ {R}_{t + 1} + γ * {V}_{π} ( {S}_{t + 1} ) \vert {S}_{t} = s ]$$
where:
V_{π}(s) is a value of state s,
E_{π}[Rₜ₊₁] is an expected value of an immediate reward,
E_{π}[γ*V_{π}(Sₜ₊₁)] is a discounted value of a next state,
Sₜ=s is a value if an agent starts at state s,
and where:
$${R}_{t + 1} = [ {Cost}_{demand} ( t + 1 ) + {Cost}_{tou} ( t + 1 ) + {Cost}_{battery \_ wear} ( t + 1 ) - {Profit}_{operations} ( t + 1 ) ]$$
and:
Cost_{demand} is a demand charge implications for a time step,
Costₜₒᵤ is a time of use (tou) charge for a time step,
Profitₒₚₑᵣₐₜᵢₒₙₛ is a value of operating the EV,
Sₜ is a state at time t,
Rₜ(s) is a reward at time t given state s,
Vₓ(s) is a value of acting on policy π at state s,
E_{π}() is an expected value, and
γ is a fractional discount of future value.

37. The system of claim 23, wherein the depot controller determines the start time and charging duration by executing instructions, that when executed by the processor, produce a charging schedule for the EV, a schedule for the at least one charger, and an aggregate power use schedule for the depot.

38. The system of claim 23, wherein the depot controller executes instructions, that when executed by the processor, determines the charging priority for the EV based on the schedule of the EV, availability of a charger of the at least one charger, and availability of power upon arrival of the EV at the depot.

39. The system of claim 23, wherein the depot controller executes instructions, that when executed by the processor, determine the charging priority for the EV based on at least one of a departure time of the EV from the depot or a total charging time needed to charge the EV to the SoC goal.

40. The system of claim 23, wherein the depot controller executes instructions, that when executed by the processor, determine the charging priority for the EV by determining a hysteresis value for availability of a charger of the at least one charger and a charging power allocation to increase efficiency of charging over time by preventing delays when a higher priority EV displaces an EV currently being charged.

41. The system of claim 23, wherein the depot controller executes instructions, that when executed by the processor, trigger a recalculation of the charging priority of the EV when the EV is removed from charging prematurely where the SoC goal has not been reached, the selected charger or EV faults to prevent the SoC goal from being reached, or the depot experiences a power outage during charging of the EV.

42. The system of claim 23, wherein the depot controller executes instructions, that when executed by the processor, trigger a recalculation of the charging priority of the EV as a result of an SoC change of the EV or a schedule change of the EV as a result of a weather change or weather forecast change.

43. The system of claim 23, wherein the depot controller executes instructions, that when executed by the processor, trigger a recalculation of the charging priority of the EV as a result of addition of a new EV or a previously unserved EV to a fleet of EVs serviced by the depot or a new route added for service by the fleet of EVs serviced by the depot.

44. The system of claim 23, wherein a charger of the at least one charger is bi-directional and the depot controller executes instructions, that when executed by the processor, determine that the EV has an SoC at or above its SoC goal and initiates transfer of energy from the EV to a utility grid for electrical arbitrage or local storage for later use at the depot.
